(19) United States
(12) Patent Application Publication
(10) Pub. No.: US 2026/0081569 A1
(43) Pub. Date: Mar. 19, 2026

(54) APPARATUS, SYSTEM, AND METHOD OF AN AMPLIFIER-OSCILLATOR

(71) Applicant: MobilEye Vision Technologies Ltd., Jerusalem (IL)

(72) Inventor: Naftali Landsberg, Kiryat Ono (IL)

(73) Assignee: MobilEye Vision Technologies Ltd., Jerusalem (IL)

(21) Appl. No.: 19/286,756

(22) Filed: Jul. 31, 2025

Related U.S. Application Data
(60) Provisional application No. 63/696,815, filed on Sep. 19, 2024.

(51) Int. Cl. H03F 3/19; G01S 7/03; G01S 7/35; H03B 5/12

(52) U.S. Cl. CPC H03F 3/19; G01S 7/03; H03B 5/12; G01S 7/352; H03F 2200/451

(57) ABSTRACT

For example, an Amplifier-Oscillator (AMP-OSC) may be switchable between an amplifying mode and an oscillating mode based on a control input. For example, the AMP-OSC may include an input terminal; an output terminal; and an AMP-OSC core connected between the input terminal and the output terminal. For example, the AMP-OSC core may be operable at an amplification core-mode based on a first setting of the control input corresponding to the amplifying mode, and operable at an oscillation core-mode based on a second setting of the control input corresponding to the oscillating mode. For example, at the amplification core-mode, the AMP-OSC core may provide an amplified signal to the output terminal by amplifying an input signal from the input terminal. For example, at the oscillation core-mode, the AMP-OSC core may generate an oscillating signal, and may provide the oscillating signal to the output terminal.

### CROSS-REFERENCE

This application claims the benefit of and priority from U.S. Provisional Patent Application No. 63/696,815, entitled “APPARATUS, SYSTEM, AND METHOD OF AN AMPLIFIER-OSCILLATOR”, filed Sep. 19, 2024, the entire disclosure of which is incorporated herein by reference.

### BACKGROUND

An amplifier may be utilized by various devices, for example, to amplify an input signal, for example, to provide an amplified signal.

An oscillator may be utilized by various devices, for example, to generate an oscillating signal, for example, at a predefined frequency.

### BRIEF DESCRIPTION OF THE DRAWINGS

For simplicity and clarity of illustration, elements shown in the figures have not necessarily been drawn to scale. For example, the dimensions of some of the elements may be exaggerated relative to other elements for clarity of presentation. Furthermore, reference numerals may be repeated among the figures to indicate corresponding or analogous elements. The figures are listed below.

FIG. 1 is a schematic block diagram illustration of a vehicle implementing a radar, in accordance with some demonstrative aspects.

FIG. 2 is a schematic block diagram illustration of a robot implementing a radar, in accordance with some demonstrative aspects.

FIG. 3 is a schematic block diagram illustration of a radar apparatus, in accordance with some demonstrative aspects.

FIG. 4 is a schematic block diagram illustration of a Frequency-Modulated Continuous Wave (FMCW) radar apparatus, in accordance with some demonstrative aspects.

FIG. 5 is a schematic illustration of an extraction scheme, which may be implemented to extract range and speed (Doppler) estimations from digital reception radar data values, in accordance with some demonstrative aspects.

FIG. 6 is a schematic illustration of an angle-determination scheme, which may be implemented to determine Angle of Arrival (AoA) information based on an incoming radio signal received by a receive antenna array, in accordance with some demonstrative aspects.

FIG. 7 is a schematic illustration of a Multiple-Input-Multiple-Output (MIMO) radar antenna scheme, which may be implemented based on a combination of Transmit (Tx) and Receive (Rx) antennas, in accordance with some demonstrative aspects.

FIG. 8 is a schematic block diagram illustration of elements of a radar device including a radar frontend and a radar processor, in accordance with some demonstrative aspects.

FIG. 9 is a schematic illustration of a radar system including a plurality of radar devices implemented in a vehicle, in accordance with some demonstrative aspects.

FIG. 10 is a schematic illustration of an apparatus including an Amplifier-Oscillator (AMP-OSC), in accordance with some demonstrative aspects.

FIG. 11 is a schematic illustration of an AMP-OSC, in accordance with some demonstrative aspects.

FIG. 12 is a schematic illustration of an AMP-OSC, in accordance with some demonstrative aspects.

FIG. 13 is a schematic illustration of an AMP-OSC, in accordance with some demonstrative aspects.

FIG. 14 is a schematic illustration of an AMP-OSC, in accordance with some demonstrative aspects.

FIG. 15 is a schematic illustration of an AMP-OSC, in accordance with some demonstrative aspects.

FIG. 16 is a schematic illustration of an AMP-OSC, in accordance with some demonstrative aspects.

FIG. 17 is a schematic illustration of an AMP-OSC, in accordance with some demonstrative aspects.

FIG. 18 is a schematic illustration of an AMP-OSC, in accordance with some demonstrative aspects.

FIG. 19 is a schematic illustration of a switchable winding, in accordance with some demonstrative aspects.

FIG. 20 is a schematic illustration of a switchable winding, in accordance with some demonstrative aspects.

FIG. 21 is a schematic illustration of an AMP-OSC, in accordance with some demonstrative aspects.

FIG. 22 is a schematic flow chart illustration of a method of an AMP-OSC, in accordance with some demonstrative aspects.

FIG. 23 is a schematic illustration of a product of manufacture, in accordance with some demonstrative aspects.

### DETAILED DESCRIPTION

In the following detailed description, numerous specific details are set forth in order to provide a thorough understanding of some aspects. However, it will be understood by persons of ordinary skill in the art that some aspects may be practiced without these specific details. In other instances, well-known methods, procedures, components, units and/or circuits have not been described in detail so as not to obscure the discussion.

Discussions herein utilizing terms such as, for example, “processing”, “computing”, “calculating”, “determining”, “establishing”, “analyzing”, “checking”, or the like, may refer to operation(s) and/or process(es) of a computer, a computing platform, a computing system, or other electronic computing device, that manipulate and/or transform data represented as physical (e.g., electronic) quantities within the computer's registers and/or memories into other data similarly represented as physical quantities within the computer's registers and/or memories or other information storage medium that may store instructions to perform operations and/or processes.

The terms “plurality” and “a plurality”, as used herein, include, for example, “multiple” or “two or more”. For example, “a plurality of items” includes two or more items.

The words “exemplary” and “demonstrative” are used herein to mean “serving as an example, instance, demonstration, or illustration”. Any aspect, or design described herein as “exemplary” or “demonstrative” is not necessarily to be construed as preferred or advantageous over other aspects, or designs.

References to “one aspect”, “an aspect”, “demonstrative aspect”, “various aspects” etc., indicate that the aspect(s) so described may include a particular feature, structure, or characteristic, but not every aspect necessarily includes the particular feature, structure, or characteristic. Further, repeated use of the phrase “in one aspect” does not necessarily refer to the same aspect, although it may.

As used herein, unless otherwise specified the use of the ordinal adjectives “first”, “second”, “third” etc., to describe a common object, merely indicate that different instances of like objects are being referred to, and are not intended to imply that the objects so described must be in a given sequence, either temporally, spatially, in ranking, or in any other manner.

The phrases “at least one” and “one or more” may be understood to include a numerical quantity greater than or equal to one, e.g., one, two, three, four, [ . . . ], etc. The phrase “at least one of” with regard to a group of elements may be used herein to mean at least one element from the group consisting of the elements. For example, the phrase “at least one of” with regard to a group of elements may be used herein to mean one of the listed elements, a plurality of one of the listed elements, a plurality of individual listed elements, or a plurality of a multiple of individual listed elements.

The term “data” as used herein may be understood to include information in any suitable analog or digital form, e.g., provided as a file, a portion of a file, a set of files, a signal or stream, a portion of a signal or stream, a set of signals or streams, and the like. Further, the term “data” may also be used to mean a reference to information, e.g., in form of a pointer. The term “data”, however, is not limited to the aforementioned examples and may take various forms and/or may represent any information as understood in the art.

The terms “processor” or “controller” may be understood to include any kind of technological entity that allows handling of any suitable type of data and/or information. The data and/or information may be handled according to one or more specific functions executed by the processor or controller. Further, a processor or a controller may be understood as any kind of circuit, e.g., any kind of analog or digital circuit. A processor or a controller may thus be or include an analog circuit, digital circuit, mixed-signal circuit, logic circuit, processor, microprocessor, Central Processing Unit (CPU), Graphics Processing Unit (GPU), Digital Signal Processor (DSP), Field Programmable Gate Array (FPGA), integrated circuit, Application Specific Integrated Circuit (ASIC), and the like, or any combination thereof. Any other kind of implementation of the respective functions, which will be described below in further detail, may also be understood as a processor, controller, or logic circuit. It is understood that any two (or more) processors, controllers, or logic circuits detailed herein may be realized as a single entity with equivalent functionality or the like, and conversely that any single processor, controller, or logic circuit detailed herein may be realized as two (or more) separate entities with equivalent functionality or the like.

The term “memory” is understood as a computer-readable medium (e.g., a non-transitory computer-readable medium) in which data or information can be stored for retrieval. References to “memory” may thus be understood as referring to volatile or non-volatile memory, including random access memory (RAM), read-only memory (ROM), flash memory, solid-state storage, magnetic tape, hard disk drive, optical drive, among others, or any combination thereof. Registers, shift registers, processor registers, data buffers, among others, are also embraced herein by the term memory. The term “software” may be used to refer to any type of executable instruction and/or logic, including firmware.

A “vehicle” may be understood to include any type of driven object. By way of example, a vehicle may be a driven object with a combustion engine, an electric engine, a reaction engine, an electrically driven object, a hybrid driven object, or a combination thereof. A vehicle may be, or may include, an automobile, a bus, a mini bus, a van, a truck, a mobile home, a vehicle trailer, a motorcycle, a bicycle, a tricycle, a train locomotive, a train wagon, a moving robot, a personal transporter, a boat, a ship, a submersible, a submarine, a drone, an aircraft, a rocket, among others.

A “ground vehicle” may be understood to include any type of vehicle, which is configured to traverse the ground, e.g., on a street, on a road, on a track, on one or more rails, off-road, or the like.

An “autonomous vehicle” may describe a vehicle capable of implementing at least one navigational change without driver input. A navigational change may describe or include a change in one or more of steering, braking, acceleration/deceleration, or any other operation relating to movement, of the vehicle. A vehicle may be described as autonomous even in case the vehicle is not fully autonomous, for example, fully operational with driver or without driver input. Autonomous vehicles may include those vehicles that can operate under driver control during certain time periods, and without driver control during other time periods. Additionally or alternatively, autonomous vehicles may include vehicles that control only some aspects of vehicle navigation, such as steering, e.g., to maintain a vehicle course between vehicle lane constraints, or some steering operations under certain circumstances, e.g., not under all circumstances, but may leave other aspects of vehicle navigation to the driver, e.g., braking or braking under certain circumstances. Additionally or alternatively, autonomous vehicles may include vehicles that share the control of one or more aspects of vehicle navigation under certain circumstances, e.g., hands-on, such as responsive to a driver input; and/or vehicles that control one or more aspects of vehicle navigation under certain circumstances, e.g., hands-off, such as independent of driver input. Additionally or alternatively, autonomous vehicles may include vehicles that control one or more aspects of vehicle navigation under certain circumstances, such as under certain environmental conditions, e.g., spatial areas, roadway conditions, or the like. In some aspects, autonomous vehicles may handle some or all aspects of braking, speed control, velocity control, steering, and/or any other additional operations, of the vehicle. An autonomous vehicle may include those vehicles that can operate without a driver. The level of autonomy of a vehicle may be described or determined by the Society of Automotive Engineers (SAE) level of the vehicle, e.g., as defined by the SAE, for example in SAE J3016 2018: Taxonomy and definitions for terms related to driving automation systems for on road motor vehicles, or by other relevant professional organizations. The SAE level may have a value ranging from a minimum level, e.g., level 0 (illustratively, substantially no driving automation), to a maximum level, e.g., level 5 (illustratively, full driving automation).

An “assisted vehicle” may describe a vehicle capable of informing a driver or occupant of the vehicle of sensed data or information derived therefrom.

The phrase “vehicle operation data” may be understood to describe any type of feature related to the operation of a vehicle. By way of example, “vehicle operation data” may describe the status of the vehicle, such as, the type of tires of the vehicle, the type of vehicle, and/or the age of the manufacturing of the vehicle. More generally, “vehicle operation data” may describe or include static features or static vehicle operation data (illustratively, features or data not changing over time). As another example, additionally or alternatively, “vehicle operation data” may describe or include features changing during the operation of the vehicle, for example, environmental conditions, such as weather conditions or road conditions during the operation of the vehicle, fuel levels, fluid levels, operational parameters of the driving source of the vehicle, or the like. More generally, “vehicle operation data” may describe or include varying features or varying vehicle operation data (illustratively, time varying features or data).

Some aspects may be used in conjunction with various devices and systems, for example, a radar sensor, a radar device, a radar system, a vehicle, a vehicular system, an autonomous vehicular system, a vehicular communication system, a vehicular device, an airborne platform, a waterborne platform, road infrastructure, sports-capture infrastructure, city monitoring infrastructure, static infrastructure platforms, indoor platforms, moving platforms, robot platforms, industrial platforms, a sensor device, a User Equipment (UE), a Mobile Device (MD), a wireless station (STA), a sensor device, a non-vehicular device, a mobile or portable device, and the like.

Some aspects may be used in conjunction with Radio Frequency (RF) systems, radar systems, vehicular radar systems, autonomous systems, robotic systems, detection systems, or the like.

Some demonstrative aspects may be used in conjunction with an RF frequency in a frequency band having a starting frequency above 10 Gigahertz (GHz), for example, a frequency band having a starting frequency between 10 GHz and 120 GHz. For example, some demonstrative aspects may be used in conjunction with an RF frequency having a starting frequency above 30 GHz, for example, above 45 GHZ, e.g., above 60 GHz. For example, some demonstrative aspects may be used in conjunction with an automotive radar frequency band, e.g., a frequency band between 76 GHz and 81 GHz. However, other aspects may be implemented utilizing any other suitable frequency bands, for example, a frequency band above 140 GHz, a frequency band of 300 GHz, a sub Terahertz (THz) band, a THz band, an Infra-Red (IR) band, and/or any other frequency band.

As used herein, the term “circuitry” may refer to, be part of, or include, an Application Specific Integrated Circuit (ASIC), an integrated circuit, an electronic circuit, a processor (shared, dedicated, or group), and/or memory (shared, dedicated, or group), that execute one or more software or firmware programs, a combinational logic circuit, and/or other suitable hardware components that provide the described functionality In some aspects, some functions associated with the circuitry may be implemented by one or more software or firmware modules. In some aspects, circuitry may include logic, at least partially operable in hardware.

The term “logic” may refer, for example, to computing logic embedded in circuitry of a computing apparatus and/or computing logic stored in a memory of a computing apparatus. For example, the logic may be accessible by a processor of the computing apparatus to execute the computing logic to perform computing functions and/or operations. In one example, logic may be embedded in various types of memory and/or firmware, e.g., silicon blocks of various chips and/or processors. Logic may be included in, and/or implemented as part of, various circuitry, e.g., radio circuitry, receiver circuitry, control circuitry, transmitter circuitry, transceiver circuitry, processor circuitry, and/or the like. In one example, logic may be embedded in volatile memory and/or non-volatile memory, including random access memory, read only memory, programmable memory, magnetic memory, flash memory, persistent memory, and/or the like. Logic may be executed by one or more processors using memory, e.g., registers, buffers, stacks, and the like, coupled to the one or more processors, e.g., as necessary to execute the logic.

The term “communicating” as used herein with respect to a signal includes transmitting the signal and/or receiving the signal. For example, an apparatus, which is capable of communicating a signal, may include a transmitter to transmit the signal, and/or a receiver to receive the signal. The verb communicating may be used to refer to the action of transmitting or the action of receiving. In one example, the phrase “communicating a signal” may refer to the action of transmitting the signal by a transmitter, and may not necessarily include the action of receiving the signal by a receiver. In another example, the phrase “communicating a signal” may refer to the action of receiving the signal by a receiver, and may not necessarily include the action of transmitting the signal by a transmitter.

The term “antenna”, as used herein, may include any suitable configuration, structure, and/or arrangement of one or more antenna elements, components, units, assemblies, and/or arrays. In some aspects, the antenna may implement transmit and receive functionalities using separate transmit and receive antenna elements. In some aspects, the antenna may implement transmit and receive functionalities using common and/or integrated transmit/receive elements. The antenna may include, for example, a phased array antenna, a MIMO (Multiple-Input Multiple-Output) array antenna, a single element antenna, a set of switched beam antennas, and/or the like. In one example, an antenna may be implemented as a separate element or an integrated element, for example, as an on-module antenna, an on-chip antenna, or according to any other antenna architecture.

Some demonstrative aspects are described herein with respect to RF radar signals. However, other aspects may be implemented with respect to, or in conjunction with, any other radar signals, wireless signals, IR signals, acoustic signals, optical signals, wireless communication signals, communication scheme, network, standard, and/or protocol. For example, some demonstrative aspects may be implemented with respect to systems, e.g., Light Detection Ranging (LiDAR) systems, and/or sonar systems, utilizing light and/or acoustic signals.

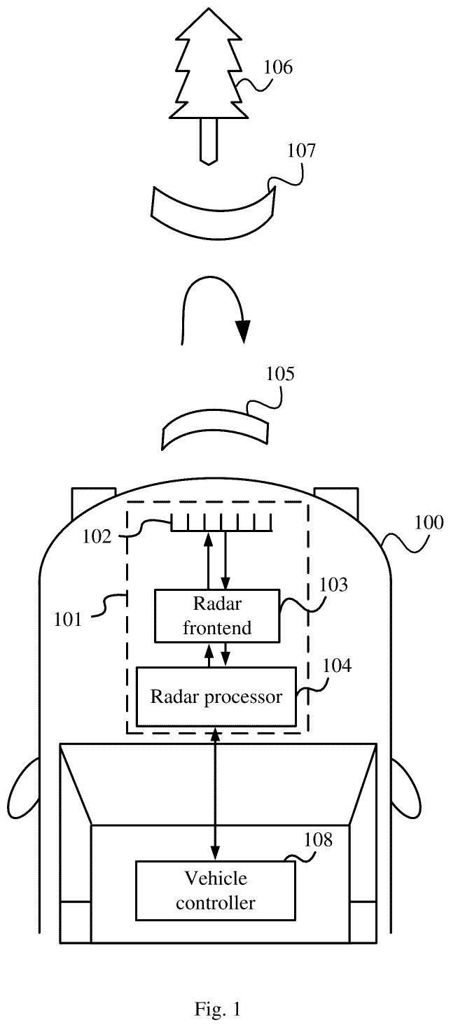

Reference is now made to FIG. 1, which schematically illustrates a block diagram of a vehicle 100 implementing a radar, in accordance with some demonstrative aspects.

In some demonstrative aspects, vehicle 100 may include a car, a truck, a motorcycle, a bus, a train, an airborne vehicle, a waterborne vehicle, a cart, a golf cart, an electric cart, a road agent, or any other vehicle.

In some demonstrative aspects, vehicle 100 may include a radar device 101, e.g., as described below. For example, radar device 101 may include a radar detecting device, a radar sensing device, a radar sensor, or the like, e.g., as described below.

In some demonstrative aspects, radar device 101 may be implemented as part of a vehicular system, for example, a system to be implemented and/or mounted in vehicle 100.

In one example, radar device 101 may be implemented as part of an autonomous vehicle system, an automated driving system, an assisted vehicle system, a driver assistance and/or support system, and/or the like.

For example, radar device 101 may be installed in vehicle 100 for detection of nearby objects, e.g., for autonomous driving.

In some demonstrative aspects, radar device 101 may be configured to detect targets in a vicinity of vehicle 100, e.g., in a far vicinity and/or a near vicinity, for example, using RF and analog chains, capacitor structures, large spiral transformers and/or any other electronic or electrical elements, e.g., as described below.

In one example, radar device 101 may be mounted onto, placed, e.g., directly, onto, or attached to, vehicle 100.

In some demonstrative aspects, vehicle 100 may include a plurality of radar aspects, vehicle 100 may include a single radar device 101.

In some demonstrative aspects, vehicle 100 may include a plurality of radar devices 101, which may be configured to cover a field of view of 360 degrees around vehicle 100.

In other aspects, vehicle 100 may include any other suitable count, arrangement, and/or configuration of radar devices and/or units, which may be suitable to cover any other field of view, e.g., a field of view of less than 360 degrees.

In some demonstrative aspects, radar device 101 may be implemented as a component in a suite of sensors used for driver assistance and/or autonomous vehicles, for example, due to the ability of radar to operate in nearly all-weather conditions.

In some demonstrative aspects, radar device 101 may be configured to support autonomous vehicle usage, e.g., as described below.

In one example, radar device 101 may determine a class, a location, an orientation, a velocity, an intention, a perceptional understanding of the environment, and/or any other information corresponding to an object in the environment.

In another example, radar device 101 may be configured to determine one or more parameters and/or information for one or more operations and/or tasks, e.g., path planning, and/or any other tasks.

In some demonstrative aspects, radar device 101 may be configured to map a scene by measuring targets' echoes (reflectivity) and discriminating them, for example, mainly in range, velocity, azimuth and/or elevation, e.g., as described below.

In some demonstrative aspects, radar device 101 may be configured to detect, and/or sense, one or more objects, which are located in a vicinity, e.g., a far vicinity and/or a near vicinity, of the vehicle 100, and to provide one or more parameters, attributes, and/or information with respect to the objects.

In some demonstrative aspects, the objects may include road users, such as other vehicles, pedestrians; road objects and markings, such as traffic signs, traffic lights, lane markings, road markings, road elements, e.g., a pavement-road meeting, a road edge, a road profile, road roughness (or smoothness); general objects, such as a hazard, e.g., a tire, a box, a crack in the road surface; and/or the like.

In some demonstrative aspects, the one or more parameters, attributes and/or information with respect to the object may include a range of the objects from the vehicle 100, an angle of the object with respect to the vehicle 100, a location of the object with respect to the vehicle 100, a relative speed of the object with respect to vehicle 100, and/or the like.

In some demonstrative aspects, radar device 101 may include a Multiple Input Multiple Output (MIMO) radar device 101, e.g., as described below.

In one example, the MIMO radar device may be configured to utilize “spatial filtering” processing, for example, beamforming and/or any other mechanism, for one or both of Transmit (Tx) signals and/or Receive (Rx) signals.

Some demonstrative aspects are described below with respect to a radar device, e.g., radar device 101, implemented as a MIMO radar. However, in other aspects, radar device 101 may be implemented as any other type of radar utilizing a plurality of antenna elements, e.g., a Single Input Multiple Output (SIMO) radar or a Multiple Input Single output (MISO) radar.

Some demonstrative aspects may be implemented with respect to a radar device, e.g., radar device 101, implemented as a MIMO radar, e.g., as described below. However, in other aspects, radar device 101 may be implemented as any other type of radar, for example, an Electronic Beam Steering radar, a Synthetic Aperture Radar (SAR), adaptive and/or cognitive radars that change their transmission according to the environment and/or ego state, a reflect array radar, or the like.

In some demonstrative aspects, radar device 101 may include an antenna arrangement 102, a radar frontend 103 configured to communicate radar signals via the antenna arrangement 102, and a radar processor 104 configured to generate radar information based on the radar signals, e.g., as described below.

In some demonstrative aspects, radar processor 104 may be configured to process radar information of radar device 101 and/or to control one or more operations of radar device 101, e.g., as described below.

In some demonstrative aspects, radar processor 104 may include, or may be implemented, partially or entirely, by circuitry and/or logic, e.g., one or more processors including circuitry and/or logic, memory circuitry and/or logic. Additionally or alternatively, one or more functionalities of radar processor 104 may be implemented by logic, which may be executed by a machine and/or one or more processors, e.g., as described below.

In one example, radar processor 104 may include at least one memory, e.g., coupled to the one or more processors, which may be configured, for example, to store, e.g., at least temporarily, at least some of the information processed by the one or more processors and/or circuitry, and/or which may be configured to store logic to be utilized by the processors and/or circuitry.

In other aspects, radar processor 104 may be implemented by one or more additional or alternative elements of vehicle 100.

In some demonstrative aspects, radar frontend 103 may include, for example, one or more (radar) transmitters, and one or more (radar) receivers, e.g., as described below.

In some demonstrative aspects, antenna arrangement 102 may include a plurality of antennas to communicate the radar signals. For example, antenna arrangement 102 may include multiple transmit antennas in the form of a transmit antenna array, and multiple receive antennas in the form of a receive antenna array. In another example, antenna arrangement 102 may include one or more antennas used both as transmit and receive antennas. In the latter case, the radar frontend 103, for example, may include a duplexer or a circulator, e.g., a circuit to separate transmitted signals from received signals.

In some demonstrative aspects, as shown in FIG. 1, the radar frontend 103 and the antenna arrangement 102 may be controlled, e.g., by radar processor 104, to transmit a radio transmit signal 105.

In some demonstrative aspects, as shown in FIG. 1, the radio transmit signal 105 may be reflected by an object 106, resulting in an echo 107.

In some demonstrative aspects, the radar device 101 may receive the echo 107, e.g., via antenna arrangement 102 and radar frontend 103, and radar processor 104 may generate radar information, for example, by calculating information about position, radial velocity (Doppler), and/or direction of the object 106, e.g., with respect to vehicle 100.

In some demonstrative aspects, radar processor 104 may be configured to provide the radar information to a vehicle controller 108 of the vehicle 100, e.g., for autonomous driving of the vehicle 100.

In some demonstrative aspects, at least part of the functionality of radar processor 104 may be implemented as part of vehicle controller 108. In other aspects, the functionality of radar processor 104 may be implemented as part of any other element of radar device 101 and/or vehicle 100. In other aspects, radar processor 104 may be implemented, as a separate part of, or as part of any other element of radar device 101 and/or vehicle 100.

In some demonstrative aspects, vehicle controller 108 may be configured to control one or more functionalities, modes of operation, components, devices, systems, and/or elements of vehicle 100.

In some demonstrative aspects, vehicle controller 108 may be configured to control one or more vehicular systems of vehicle 100, e.g., as described below.

In some demonstrative aspects, the vehicular systems may include, for example, a steering system, a braking system, a driving system, and/or any other system of the vehicle 100.

In some demonstrative aspects, vehicle controller 108 may configured to control radar device 101, and/or to process one or parameters, attributes and/or information from radar device 101.

In some demonstrative aspects, vehicle controller 108 may be configured, for example, to control the vehicular systems of the vehicle 100, for example, based on radar information from radar device 101 and/or one or more other sensors of the vehicle 100, e.g., Light Detection and Ranging (LIDAR) sensors, camera sensors, and/or the like.

In one example, vehicle controller 108 may control the steering system, the braking system, and/or any other vehicular systems of vehicle 100, for example, based on the information from radar device 101, e.g., based on one or more objects detected by radar device 101.

In other aspects, vehicle controller 108 may be configured to control any other additional or alternative functionalities of vehicle 100.

Some demonstrative aspects are described herein with respect to a radar device 101 implemented in a vehicle, e.g., vehicle 100. In other aspects a radar device, e.g., radar device 101, may be implemented as part of any other element of a traffic system or network, for example, as part of a road infrastructure, and/or any other element of a traffic network or system. Other aspects may be implemented with respect to any other system, environment, and/or apparatus, which may be implemented in any other object, environment, location, or place. For example, radar device 101 may be part of a non-vehicular device, which may be implemented, for example, in an indoor location, a stationary infrastructure outdoors, or any other location.

In some demonstrative aspects, radar device 101 may be configured to support security usage. In one example, radar device 101 may be configured to determine a nature of an operation, e.g., a human entry, an animal entry, an environmental movement, and the like, to identity a threat level of a detected event, and/or any other additional or alternative operations.

Some demonstrative aspects may be implemented with respect to any other additional or alternative devices and/or systems, for example, for a robot, e.g., as described below.

In other aspects, radar device 101 may be configured to support any other usages and/or applications.

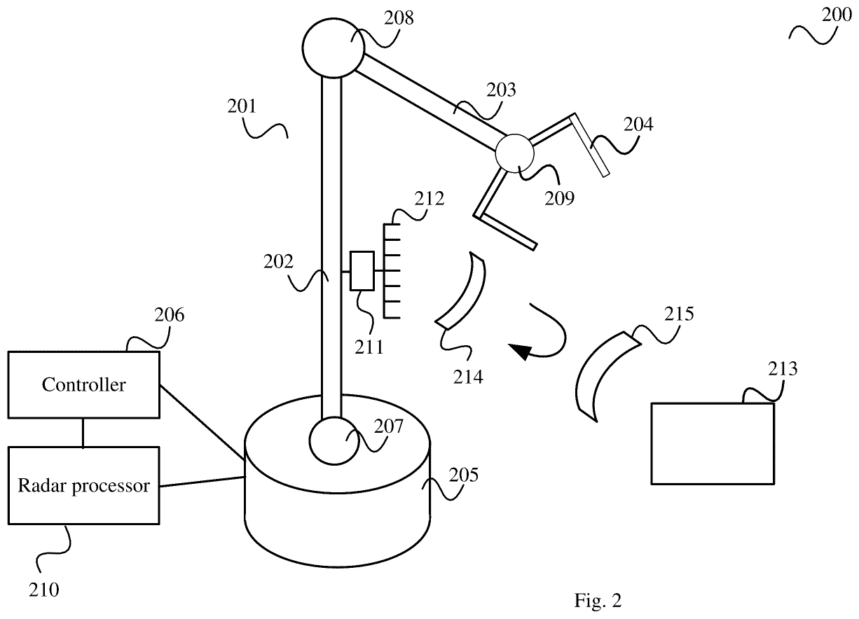

Reference is now made to FIG. 2, which schematically illustrates a block diagram of a robot 200 implementing a radar, in accordance with some demonstrative aspects.

In some demonstrative aspects, robot 200 may include a robot arm 201. The robot 200 may be implemented, for example, in a factory for handling an object 213, which may be, for example, a part that should be affixed to a product that is being manufactured. The robot arm 201 may include a plurality of movable members, for example, movable members 202, 203, 204, and a support 205. Moving the movable members 202, 203, and/or 204 of the robot arm 201, e.g., by actuation of associated motors, may allow physical interaction with the environment to carry out a task, e.g., handling the object 213.

In some demonstrative aspects, the robot arm 201 may include a plurality of joint elements, e.g., joint elements 207, 208, 209, which may connect, for example, the members 202, 203, and/or 204 with each other, and with the support 205. For example, a joint element 207, 208, 209 may have one or more joints, each of which may provide rotatable motion, e.g., rotational motion, and/or translatory motion, e.g., displacement, to associated members and/or motion of members relative to each other. The movement of the members 202, 203, 204 may be initiated by suitable actuators.

In some demonstrative aspects, the member furthest from the support 205, e.g., member 204, may also be referred to as the end-effector 204 and may include one or more tools, such as, a claw for gripping an object, a welding tool, or the like. Other members, e.g., members 202, 203, closer to the support 205, may be utilized to change the position of the end-effector 204, e.g., in three-dimensional space. For example, the robot arm 201 may be configured to function similarly to a human arm, e.g., possibly with a tool at its end.

In some demonstrative aspects, robot 200 may include a (robot) controller 206 configured to implement interaction with the environment, e.g., by controlling the robot arm's actuators, according to a control program, for example, in order to control the robot arm 201 according to the task to be performed.

In some demonstrative aspects, an actuator may include a component adapted to affect a mechanism or process in response to being driven. The actuator can respond to commands given by the controller 206 (the so-called activation) by performing mechanical movement. This means that an actuator, typically a motor (or electromechanical converter), may be configured to convert electrical energy into mechanical energy when it is activated (i.e., actuated).

In some demonstrative aspects, controller 206 may be in communication with a radar processor 210 of the robot 200.

In some demonstrative aspects, a radar fronted 211 and a radar antenna arrangement 212 may be coupled to the radar processor 210. In one example, radar fronted 211 and/or radar antenna arrangement 212 may be included, for example, as part of the robot arm 201.

In some demonstrative aspects, the radar frontend 211, the radar antenna arrangement 212 and the radar processor 210 may be operable as, and/or may be configured to form, a radar device. For example, antenna arrangement 212 may be configured to perform one or more functionalities of antenna arrangement 102 (FIG. 1), radar frontend 211 may be configured to perform one or more functionalities of radar frontend 103 (FIG. 1), and/or radar processor 210 may be configured to perform one or more functionalities of radar processor 104 (FIG. 1), e.g., as described above.

In some demonstrative aspects, for example, the radar frontend 211 and the antenna arrangement 212 may be controlled, e.g., by radar processor 210, to transmit a radio transmit signal 214.

In some demonstrative aspects, as shown in FIG. 2, the radio transmit signal 214 may be reflected by the object 213, resulting in an echo 215.

In some demonstrative aspects, the echo 215 may be received, e.g., via antenna arrangement 212 and radar frontend 211, and radar processor 210 may generate radar information, for example, by calculating information about position, speed (Doppler) and/or direction of the object 213, e.g., with respect to robot arm 201.

In some demonstrative aspects, radar processor 210 may be configured to provide the radar information to the robot controller 206 of the robot arm 201, e.g., to control robot arm 201. For example, robot controller 206 may be configured to control robot arm 201 based on the radar information, e.g., to grab the object 213 and/or to perform any other operation.

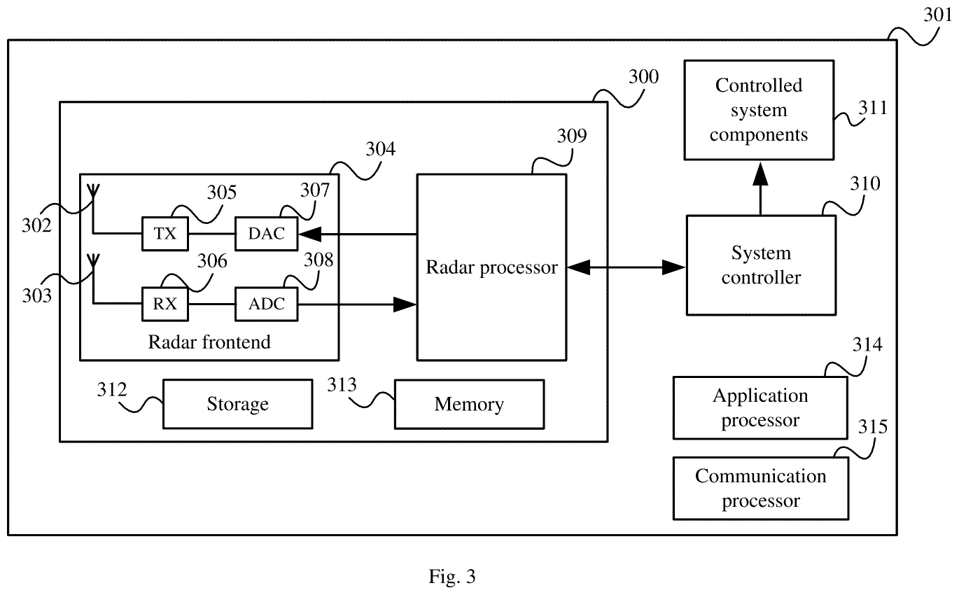

Reference is made to FIG. 3, which schematically illustrates a radar apparatus 300, in accordance with some demonstrative aspects.

In some demonstrative aspects, radar apparatus 300 may be implemented as part of a device or system 301, e.g., as described below.

For example, radar apparatus 300 may be implemented as part of, and/or may configured to perform one or more operations and/or functionalities of, the devices or systems described above with reference to FIG. 1 and/or FIG. 2. In other aspects, radar apparatus 300 may be implemented as part of any other device or system 301.

In some demonstrative aspects, radar device 300 may include an antenna arrangement, which may include one or more transmit antennas 302 and one or more receive antennas 303. In other aspects, any other antenna arrangement may be implemented.

In some demonstrative aspects, radar device 300 may include a radar frontend 304, and a radar processor 309.

In some demonstrative aspects, as shown in FIG. 3, the one or more transmit antennas 302 may be coupled with a transmitter (or transmitter arrangement) 305 of the radar frontend 304; and/or the one or more receive antennas 303 may be coupled with a receiver (or receiver arrangement) 306 of the radar frontend 304, e.g., as described below.

In some demonstrative aspects, transmitter 305 may include one or more elements, for example, an oscillator, a power amplifier and/or one or more other elements, configured to generate radio transmit signals to be transmitted by the one or more transmit antennas 302, e.g., as described below.

In some demonstrative aspects, for example, radar processor 309 may provide digital radar transmit data values to the radar frontend 304. For example, radar frontend 304 may include a Digital-to-Analog Converter (DAC) 307 to convert the digital radar transmit data values to an analog transmit signal. The transmitter 305 may convert the analog transmit signal to a radio transmit signal which is to be transmitted by transmit antennas 302.

In some demonstrative aspects, receiver 306 may include one or more elements, for example, one or more mixers, one or more filters and/or one or more other elements, configured to process, down-convert, radio signals received via the one or more receive antennas 303, e.g., as described below.

In some demonstrative aspects, for example, receiver 306 may convert a radio receive signal received via the one or more receive antennas 303 into an analog receive signal. The radar frontend 304 may include an Analog-to-Digital Converter (ADC) 308 to generate digital radar reception data values based on the analog receive signal. For example, radar frontend 304 may provide the digital radar reception data values to the radar processor 309.

In some demonstrative aspects, radar processor 309 may be configured to process the digital radar reception data values, for example, to detect one or more objects, e.g., in an environment of the device/system 301. This detection may include, for example, the determination of information including one or more of range, speed (Doppler), direction, and/or any other information, of one or more objects, e.g., with respect to the system 301.

In some demonstrative aspects, radar processor 309 may be configured to provide the determined radar information to a system controller 310 of device/system 301. For example, system controller 310 may include a vehicle controller, e.g., if device/system 301 includes a vehicular device/system, a robot controller, e.g., if device/system 301 includes a robot device/system, or any other type of controller for any other type of device/system 301.

In some demonstrative aspects, the radar information from radar processor 309 may be processed, e.g., by system controller 310 and/or any other element of system 301, for example, in combination with information from one or more other of information sources, for example, LiDAR information from a LiDAR processor, vision information from a vision-based processor, or the like.

In some demonstrative aspects, an environmental model of an environment of system 301 may be determined, e.g., by system controller 310 and/or any other element of system 301, for example, based on the radar information from radar processor 309, and/or the information from one or more other of information sources.

In some demonstrative aspects, a driving policy system, e.g., which may be implemented by system controller 310 and/or any other element of system 301, may process the environmental model, for example, to decide on one or more actions, which may be taken.

In some demonstrative aspects, system controller 310 may be configured to control one or more controlled system components 311 of the system 301, e.g., a motor, a brake, steering, and the like, e.g., by one or more corresponding actuators, for example, based on the one or more action decisions.

In some demonstrative aspects, radar device 300 may include a storage 312 or a memory 313, e.g., to store information processed by radar 300, for example, digital radar reception data values being processed by the radar processor 309, radar information generated by radar processor 309, and/or any other data to be processed by radar processor 309.

In some demonstrative aspects, device/system 301 may include, for example, an application processor 314 and/or a communication processor 315, for example, to at least partially implement one or more functionalities of system controller 310 and/or to perform communication between system controller 310, radar device 300, the controlled system components 311, and/or one or more additional elements of device/system 301.

In some demonstrative aspects, radar device 300 may be configured to generate and transmit the radio transmit signal in a form, which may support determination of range, speed, and/or direction, e.g., as described below.

For example, a radio transmit signal of a radar may be configured to include a plurality of pulses. For example, a pulse transmission may include the transmission of short high-power bursts in combination with times during which the radar device listens for echoes.

For example, in order to more optimally support a highly dynamic situation, e.g., in an automotive scenario, a Continuous Wave (CW) may instead be used as the radio transmit signal. However, a continuous wave, e.g., with constant frequency, may support velocity determination, but may not allow range determination, e.g., due to the lack of a time mark that could allow distance calculation.

In some demonstrative aspects, radio transmit signal 105 (FIG. 1) may be transmitted according to technologies such as, for example, Frequency-Modulated Continuous Wave (FMCW) radar, Phase-Modulated Continuous Wave (PMCW) radar, Orthogonal Frequency Division Multiplexing (OFDM) radar, and/or any other type of radar technology, which may support determination of range, velocity, and/or direction, e.g., as described below.

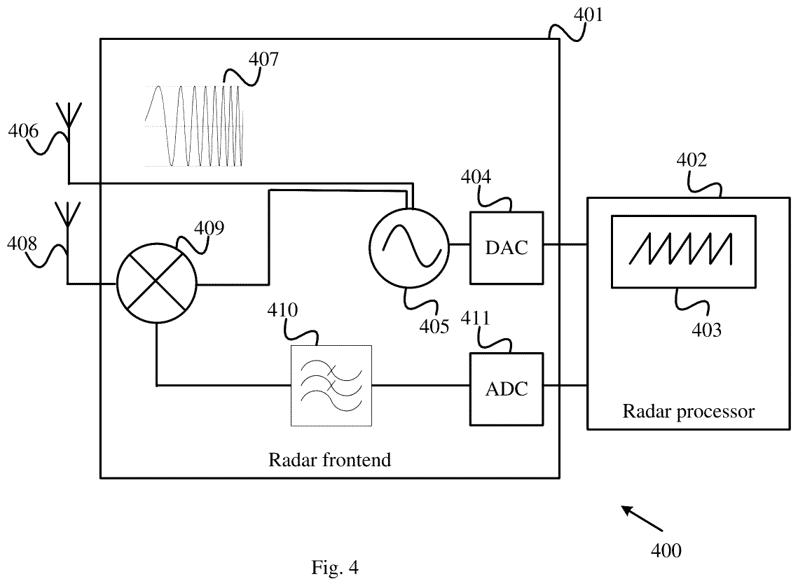

Reference is made to FIG. 4, which schematically illustrates an FMCW radar apparatus, in accordance with some demonstrative aspects.

In some demonstrative aspects, FMCW radar device 400 may include a radar frontend 401, and a radar processor 402. For example, radar frontend 304 (FIG. 3) may include one or more elements of, and/or may perform one or more operations and/or functionalities of, radar frontend 401; and/or radar processor 309 (FIG. 3) may include one or more elements of, and/or may perform one or more operations and/or functionalities of, radar processor 402.

In some demonstrative aspects, FMCW radar device 400 may be configured to communicate radio signals according to an FMCW radar technology, e.g., rather than sending a radio transmit signal with a constant frequency.

In some demonstrative aspects, radio frontend 401 may be configured to ramp up and reset the frequency of the transmit signal, e.g., periodically, for example, according to a saw tooth waveform 403. In other aspects, a triangle waveform, or any other suitable waveform may be used.

In some demonstrative aspects, for example, radar processor 402 may be configured to provide waveform 403 to frontend 401, for example, in digital form, e.g., as a sequence of digital values.

In some demonstrative aspects, radar frontend 401 may include a DAC 404 to convert waveform 403 into analog form, and to supply it to a voltage-controlled oscillator 405. For example, oscillator 405 may be configured to generate an output signal, which may be frequency-modulated in accordance with the waveform 403.

In some demonstrative aspects, oscillator 405 may be configured to generate the output signal including a radio transmit signal, which may be fed to and sent out by one or more transmit antennas 406.

In some demonstrative aspects, the radio transmit signal generated by the oscillator 405 may have the form of a sequence of chirps 407, which may be the result of the modulation of a sinusoid with the saw tooth waveform 403.

In one example, a chirp 407 may correspond to the sinusoid of the oscillator signal frequency-modulated by a “tooth” of the saw tooth waveform 403, e.g., from the minimum frequency to the maximum frequency.

In some demonstrative aspects, FMCW radar device 400 may include one or more receive antennas 408 to receive a radio receive signal. The radio receive signal may be based on the echo of the radio transmit signal, e.g., in addition to any noise, interference, or the like.

In some demonstrative aspects, radar frontend 401 may include a mixer 409 to mix the radio transmit signal with the radio receive signal into a mixed signal.

In some demonstrative aspects, radar frontend 401 may include a filter, e.g., a Low Pass Filter (LPF) 410, which may be configured to filter the mixed signal from the mixer 409 to provide a filtered signal. For example, radar frontend 401 may include an ADC 411 to convert the filtered signal into digital reception data values, which may be provided to radar processor 402. In another example, the filter 410 may be a digital filter, and the ADC 411 may be arranged between the mixer 409 and the filter 410.

In some demonstrative aspects, radar processor 402 may be configured to process the digital reception data values to provide radar information, for example, including range, speed (velocity/Doppler), and/or direction (AoA) information of one or more objects.

In some demonstrative aspects, radar processor 402 may be configured to perform a first Fast Fourier Transform (FFT) (also referred to as “range FFT”) to extract a delay response, which may be used to extract range information, and/or a second FFT (also referred to as “Doppler FFT”) to extract a Doppler shift response, which may be used to extract velocity information, from the digital reception data values.

In other aspects, any other additional or alternative methods may be utilized to extract range information. In one example, in a digital radar implementation, a correlation with the transmitted signal may be used, e.g., according to a matched filter implementation.

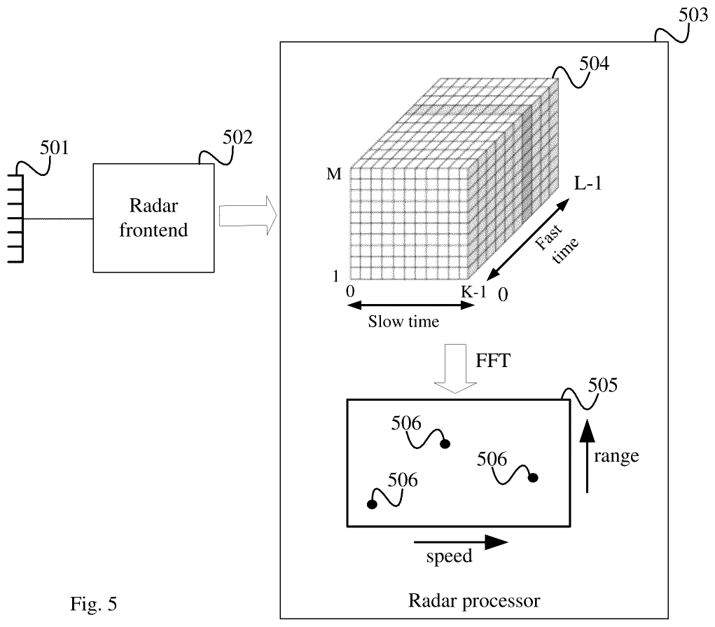

Reference is made to FIG. 5, which schematically illustrates an extraction scheme, which may be implemented to extract range and speed (Doppler) estimations from digital reception radar data values, in accordance with some demonstrative aspects. For example, radar processor 104 (FIG. 1), radar processor 210 (FIG. 2), radar processor 309 (FIG. 3), and/or radar processor 402 (FIG. 4), may be configured to extract range and/or speed (Doppler) estimations from digital reception radar data values according to one or more aspects of the extraction scheme of FIG. 5.

In some demonstrative aspects, as shown in FIG. 5, a radio receive signal, e.g., including echoes of a radio transmit signal, may be received by a receive antenna array 501. The radio receive signal may be processed by a radio radar frontend 502 to generate digital reception data values, e.g., as described above. The radio radar frontend 502 may provide the digital reception data values to a radar processor 503, which may process the digital reception data values to provide radar information, e.g., as described above.

In some demonstrative aspects, the digital reception data values may be represented in the form of a data cube 504. For example, the data cube 504 may include digitized samples of the radio receive signal, which is based on a radio signal transmitted from a transmit antenna and received by M receive antennas. In some demonstrative aspects, for example, with respect to a MIMO implementation, there may be multiple transmit antennas, and the number of samples may be multiplied accordingly.

In some demonstrative aspects, a layer of the data cube 504, for example, a horizontal layer of the data cube 504, may include samples of an antenna, e.g., a respective antenna of the M antennas.

In some demonstrative aspects, data cube 504 may include samples for K chirps. For example, as shown in FIG. 5, the samples of the chirps may be arranged in a so-called “slow time”-direction.

In some demonstrative aspects, the data cube 504 may include L samples, e.g., L=512 or any other number of samples, for a chirp, e.g., per each chirp. For example, as shown in FIG. 5, the samples per chirp may be arranged in a so-called “fast time”-direction of the data cube 504.

In some demonstrative aspects, radar processor 503 may be configured to process a plurality of samples, e.g., L samples collected for each chirp and for each antenna, by a first FFT. The first FFT may be performed, for example, for each chirp and each antenna, such that a result of the processing of the data cube 504 by the first FFT may again have three dimensions, and may have the size of the data cube 504 while including values for L range bins, e.g., instead of the values for the L sampling times.

In some demonstrative aspects, radar processor 503 may be configured to process the result of the processing of the data cube 504 by the first FFT, for example, by processing the result according to a second FFT along the chirps, e.g., for each antenna and for each range bin.

For example, the first FFT may be in the “fast time” direction, and the second FFT may be in the “slow time” direction.

In some demonstrative aspects, the result of the second FFT may provide, e.g., when aggregated over the antennas, a range/Doppler (R/D) map 505. The R/D map may have FFT peaks 506, for example, including peaks of FFT output values (in terms of absolute values) for certain range/speed combinations, e.g., for range/Doppler bins. For example, a range/Doppler bin may correspond to a range bin and a Doppler bin. For example, radar processor 503 may consider a peak as potentially corresponding to an object, e.g., of the range and speed corresponding to the peak's range bin and speed bin.

In some demonstrative aspects, the extraction scheme of FIG. 5 may be implemented for an FMCW radar, e.g., FMCW radar 400 (FIG. 4), as described above. In other aspects, the extraction scheme of FIG. 5 may be implemented for any other radar type. In one example, the radar processor 503 may be configured to determine a range/Doppler map 505 from digital reception data values of a PMCW radar, an OFDM radar, or any other radar technologies. For example, in adaptive or cognitive radar, the pulses in a frame, the waveform and/or modulation may be changed over time, e.g., according to the environment.

Referring back to FIG. 3, in some demonstrative aspects, receive antenna arrangement 303 may be implemented using a receive antenna array having a plurality of receive antennas (or receive antenna elements). For example, radar processor 309 may be configured to determine an angle of arrival of the received radio signal, e.g., echo 107 (FIG. 1) and/or echo 215 (FIG. 2). For example, radar processor 309 may be configured to determine a direction of a detected object, e.g., with respect to the device/system 301, for example, based on the angle of arrival of the received radio signal, e.g., as described below.

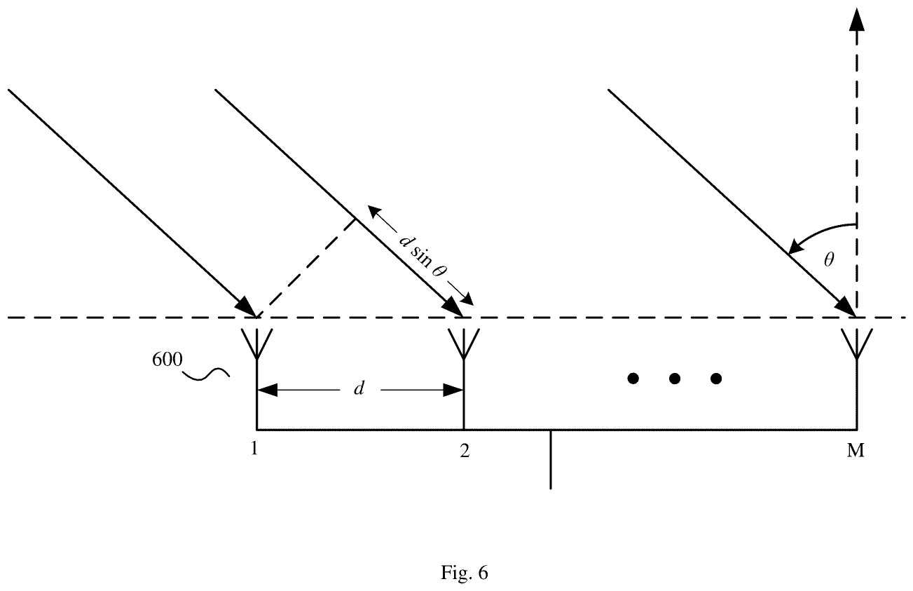

Reference is made to FIG. 6, which schematically illustrates an angle-determination scheme, which may be implemented to determine Angle of Arrival (AoA) information based on an incoming radio signal received by a receive antenna array 600, in accordance with some demonstrative aspects.

FIG. 6 depicts an angle-determination scheme based on received signals at the receive antenna array.

In some demonstrative aspects, for example, in a virtual MIMO array, the angle-determination may also be based on the signals transmitted by the array of Tx antennas.

FIG. 6 depicts a one-dimensional angle-determination scheme. Other multi-dimensional angle determination schemes, e.g., a two-dimensional scheme or a three-dimensional scheme, may be implemented.

In some demonstrative aspects, as shown in FIG. 6, the receive antenna array 600 may include M antennas (numbered, from left to right, 1 to M).

As shown by the arrows in FIG. 6, it is assumed that an echo is coming from an object located at the top left direction. Accordingly, the direction of the echo, e.g., the incoming radio signal, may be towards the bottom right. According to this example, the further to the left a receive antenna is located, the earlier it will receive a certain phase of the incoming radio signal.

For example, a phase difference, denoted Δφ, between two antennas of the receive antenna array 600 may be determined, e.g., as follows:

$$Δφ = \frac{2 π}{λ} \cdot d \cdot sin ( θ )$$

wherein λ denotes a wavelength of the incoming radio signal, d denotes a distance between the two antennas, and θ denotes an angle of arrival of the incoming radio signal, e.g., with respect to a normal direction of the array.

In some demonstrative aspects, radar processor 309 (FIG. 3) may be configured to utilize this relationship between phase and angle of the incoming radio signal, for example, to determine the angle of arrival of echoes, for example by performing an FFT, e.g., a third FFT (“angular FFT”) over the antennas.

In some demonstrative aspects, multiple transmit antennas, e.g., in the form of an antenna array having multiple transmit antennas, may be used, for example, to increase the spatial resolution, e.g., to provide high-resolution radar information. For example, a MIMO radar device may utilize a virtual MIMO radar antenna, which may be formed as a convolution of a plurality of transmit antennas convolved with a plurality of receive antennas.

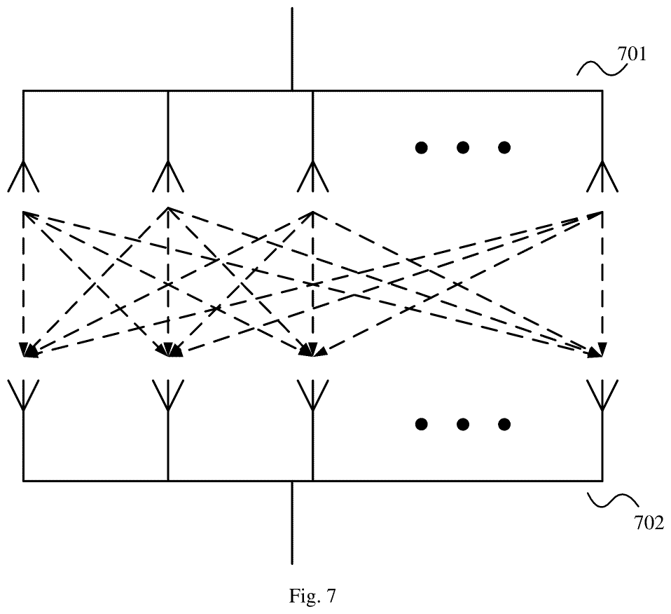

Reference is made to FIG. 7, which schematically illustrates a MIMO radar antenna scheme, which may be implemented based on a combination of Transmit (Tx) and Receive (Rx) antennas, in accordance with some demonstrative aspects.

In some demonstrative aspects, as shown in FIG. 7, a radar MIMO arrangement may include a transmit antenna array 701 and a receive antenna array 702. For example, the one or more transmit antennas 302 (FIG. 3) may be implemented to include transmit antenna array 701, and/or the one or more receive antennas 303 (FIG. 3) may be implemented to include receive antenna array 702.

In some demonstrative aspects, antenna arrays including multiple antennas both for transmitting the radio transmit signals and for receiving echoes of the radio transmit signals, may be utilized to provide a plurality of virtual channels as illustrated by the dashed lines in FIG. 7. For example, a virtual channel may be formed as a convolution, for example, as a Kronecker product, between a transmit antenna and a receive antenna, e.g., representing a virtual steering vector of the MIMO radar.

In some demonstrative aspects, a transmit antenna, e.g., each transmit antenna, may be configured to send out an individual radio transmit signal, e.g., having a phase associated with the respective transmit antenna.

For example, an array of N transmit antennas and M receive antennas may be implemented to provide a virtual MIMO array of size N×M. For example, the virtual MIMO array may be formed according to the Kronecker product operation applied to the Tx and Rx steering vectors.

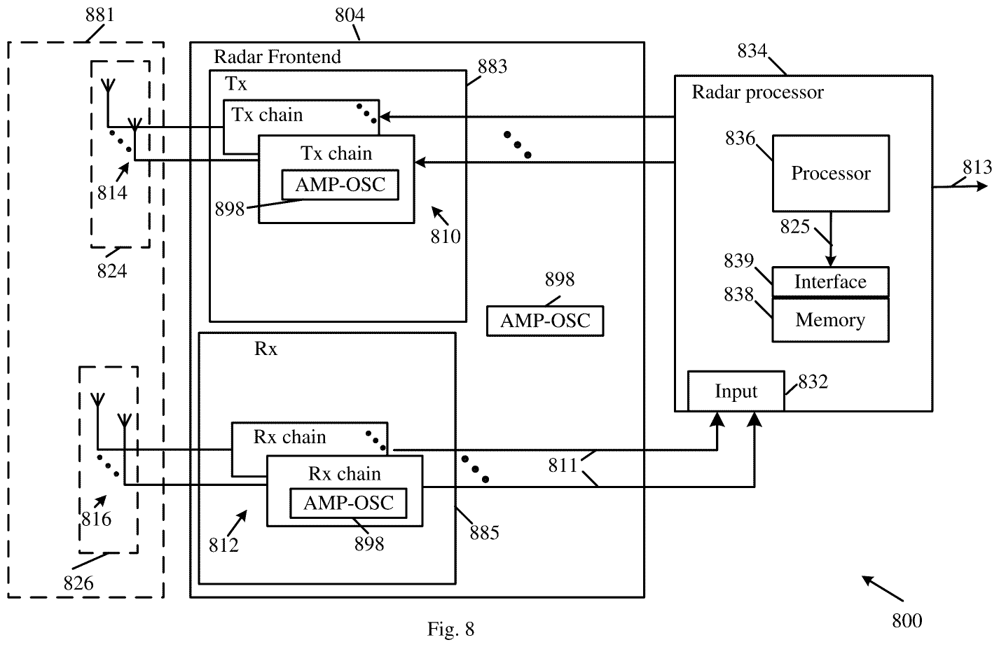

FIG. 8 is a schematic block diagram illustration of elements of a radar device 800, in accordance with some demonstrative aspects. For example, radar device 101 (FIG. 1), radar device 300 (FIG. 3), and/or radar device 400 (FIG. 4), may include one or more elements of radar device 800, and/or may perform one or more operations and/or functionalities of radar device 800.

In some demonstrative aspects, as shown in FIG. 8, radar device 800 may include a radar frontend 804 and a radar processor 834. For example, radar frontend 103 (FIG. 1), radar frontend 211 (FIG. 1), radar frontend 304 (FIG. 3), radar frontend 401 (FIG. 4), and/or radar frontend 502 (FIG. 5), may include one or more elements of radar frontend 804, and/or may perform one or more operations and/or functionalities of radar frontend 804.

In some demonstrative aspects, radar frontend 804 may be implemented as part of a MIMO radar utilizing a MIMO radar antenna 881 including a plurality of Tx antennas 814 configured to transmit a plurality of Tx RF signals (also referred to as “Tx radar signals”); and a plurality of Rx antennas 816 configured to receive a plurality of Rx RF signals (also referred to as “Rx radar signals”), for example, based on the Tx radar signals, e.g., as described below.

In some demonstrative aspects, MIMO antenna array 881, antennas 814, and/or antennas 816 may include or may be part of any type of antennas suitable for transmitting and/or receiving radar signals. For example, MIMO antenna array 881, antennas 814, and/or antennas 816, may be implemented as part of any suitable configuration, structure, and/or arrangement of one or more antenna elements, components, units, assemblies, and/or arrays. For example, MIMO antenna array 881, antennas 814, and/or antennas 816, may be implemented as part of a phased array antenna, a multiple element antenna, a set of switched beam antennas, and/or the like. In some aspects, MIMO antenna array 881, antennas 814, and/or antennas 816, may be implemented to support transmit and receive functionalities using separate transmit and receive antenna elements. In some aspects, MIMO antenna array 881, antennas 814, and/or antennas 816, may be implemented to support transmit and receive functionalities using common and/or integrated transmit/receive elements.

In some demonstrative aspects, MIMO radar antenna 881 may include a rectangular MIMO antenna array, and/or curved array, e.g., shaped to fit a vehicle design.

In other aspects, any other form, shape, and/or arrangement of MIMO radar antenna 881 may be implemented.

In some demonstrative aspects, radar frontend 804 may include one or more radios configured to generate and transmit the Tx RF signals via Tx antennas 814; and/or to process the Rx RF signals received via Rx antennas 816, e.g., as described below.

In some demonstrative aspects, radar frontend 804 may include at least one transmitter (Tx) 883 including circuitry and/or logic configured to generate and/or transmit the Tx radar signals via Tx antennas 814.

In some demonstrative aspects, radar frontend 804 may include at least one receiver (Rx) 885 including circuitry and/or logic to receive and/or process the Rx radar signals received via Rx antennas 816, for example, based on the Tx radar signals.

In some demonstrative aspects, transmitter 883, and/or receiver 885 may include circuitry; logic; Radio Frequency (RF) elements, circuitry and/or logic; baseband elements, circuitry and/or logic; modulation elements, circuitry and/or logic; demodulation elements, circuitry and/or logic; amplifiers; analog to digital and/or digital to analog converters; filters; and/or the like.

In some demonstrative aspects, transmitter 883 may include a plurality of Tx chains 810 configured to generate and transmit the Tx RF signals via Tx antennas 814, e.g., respectively; and/or receiver 885 may include a plurality of Rx chains 812 configured to receive and process the Rx RF signals received via the Rx antennas 816, e.g., respectively.

In some demonstrative aspects, radar processor 834 may be configured to generate radar information 813, for example, based on the radar signals communicated by MIMO radar antenna 881, e.g., as described below. For example, radar processor 104 (FIG. 1), radar processor 210 (FIG. 2), radar processor 309 (FIG. 3), radar processor 402 (FIG. 4), and/or radar processor 503 (FIG. 5), may include one or more elements of radar processor 834, and/or may perform one or more operations and/or functionalities of radar processor 834.

In some demonstrative aspects, radar processor 834 may be configured to generate radar information 813, for example, based on radar Rx data 811 received from the plurality of Rx chains 812. For example, radar Rx data 811 may be based on the radar Rx signals received via the Rx antennas 816.

In some demonstrative aspects, radar processor 834 may include an input 832 to receive radar input data, e.g., including the radar Rx data 811 from the plurality of Rx chains 812.

In some demonstrative aspects, radar processor 834 may include, or may be implemented, partially or entirely, by circuitry and/or logic, e.g., one or more processors including circuitry and/or logic, memory circuitry and/or logic. Additionally or alternatively, one or more functionalities of radar processor 834 may be implemented by logic, which may be executed by a machine and/or one or more processors, e.g., as described below.

In some demonstrative aspects, radar processor 834 may include at least one processor 836, which may be configured, for example, to process the radar Rx data 811, and/or to perform one or more operations, methods, and/or algorithms.

In some demonstrative aspects, radar processor 834 may include at least one memory 838, e.g., coupled to the processor 836. For example, memory 838 may be configured to store data processed by radar processor 834. For example, memory 838 may store, e.g., at least temporarily, at least some of the information processed by the processor 836, and/or logic to be utilized by the processor 836.

In some demonstrative aspects, processor 836 may interface with memory 838, for example, via a memory interface 839.

In some demonstrative aspects, processor 836 may be configured to access memory 838, e.g., to write data to memory 838 and/or to read data from memory 838, for example, via memory interface 839.

In some demonstrative aspects, memory 838 may be configured to store at least part of the radar data, e.g., some of the radar Rx data or all of the radar Rx data, for example, for processing by processor 836, e.g., as described below.

In some demonstrative aspects, memory 838 may be configured to store processed data, which may be generated by processor 836, for example, during the process of generating the radar information 813, e.g., as described below.

In some demonstrative aspects, memory 838 may be configured to store range information and/or Doppler information, which may be generated by processor 836, for example, based on the radar Rx data. In one example, the range information and/or Doppler information may be determined based on a Cross-Correlation (XCORR) operation, which may be applied to the radar Rx data. Any other additional or alternative operation, algorithm, and/or procedure may be utilized to generate the range information and/or Doppler information.

In some demonstrative aspects, memory 838 may be configured to store AoA information, which may be generated by processor 836, for example, based on the radar Rx data, the range information and/or Doppler information. In one example, the AoA information may be determined based on an AoA estimation algorithm. Any other additional or alternative operation, algorithm, and/or procedure may be utilized to generate the AoA information.

In some demonstrative aspects, radar processor 834 may be configured to generate the radar information 813 including one or more of range information, Doppler information, and/or AoA information.

In some demonstrative aspects, the radar information 813 may include Point Cloud 1 (PC1) information, for example, including raw point cloud estimations, e.g., Range, Radial Velocity, Azimuth, and/or Elevation.

In some demonstrative aspects, the radar information 813 may include additional information, which may be, for example, based on the raw point cloud estimations, and/or may be related to the raw point cloud estimations.

In some demonstrative aspects, the radar information 813 may include metadata information corresponding to the raw point cloud estimations.

In some demonstrative aspects, the radar information 813 may include, for example, information relating to a reliability level of the raw point cloud estimations, information relating to one or more parameters, conditions and/or criteria implemented in determining the raw point cloud estimations, and/or any other suitable additional or alternative information.

For example, the radar information 813 may include Log Likelihood Ratio (LLR) information corresponding to the raw point cloud estimations, Radar Cross Section (RCS) estimation information, Signal to Noise Ratio (SNR) estimation information, and/or any other suitable additional or alternative information.

In some demonstrative aspects, the radar information 813 may include Point Cloud 2 (PC2) information, which may be generated, for example, based on the PC1 information. For example, the PC2 information may include clustering information, tracking information, e.g., tracking of probabilities and/or density functions, bounding box information, classification information, orientation information, and the like. In one example, the PC2 information may be based on one or more temporal filtering techniques, which may be applied to the PC1 information, for example, for temporal filtering of multiple frames and/or multiple PC1 instances.

In some demonstrative aspects, the radar information 813 may include target tracking information corresponding to a plurality of targets in an environment of the radar device 800, e.g., as described below.

In some demonstrative aspects, radar processor 834 may be configured to generate the radar information 813 in the form of four Dimensional (4D) image information, e.g., a cube, which may represent 4D information corresponding to one or more detected targets.

In some demonstrative aspects, the 4D image information may include, for example, range values, e.g., based on the range information, velocity values, e.g., based on the Doppler information, azimuth values, e.g., based on azimuth AoA information, elevation values, e.g., based on elevation AoA information, and/or any other values.

In some demonstrative aspects, radar processor 834 may be configured to generate the radar information 813 in any other form, and/or including any other additional or alternative information.

In some demonstrative aspects, radar processor 834 may be configured to process the signals communicated via MIMO radar antenna 881 as signals of a virtual MIMO array formed by a convolution of the plurality of Rx antennas 816 and the plurality of Tx antennas 814.

In some demonstrative aspects, radar frontend 804 and/or radar processor 834 may be configured to utilize MIMO techniques, for example, to support a reduced physical array aperture, e.g., an array size, and/or utilizing a reduced number of antenna elements. For example, radar frontend 804 and/or radar processor 834 may be configured to transmit orthogonal signals via one or more Tx arrays 824 including a plurality of N elements, e.g., Tx antennas 814, and processing received signals via one or more Rx arrays 826 including a plurality of M elements, e.g., Rx antennas 816.

In some demonstrative aspects, utilizing the MIMO technique of transmission of the orthogonal signals from the Tx arrays 824 with N elements and processing the received signals in the Rx arrays 826 with M elements may be equivalent, e.g., under a far field approximation, to a radar utilizing transmission from one antenna and reception with N*M antennas. For example, radar frontend 804 and/or radar processor 834 may be configured to utilize MIMO antenna array 881 as a virtual array having an equivalent array size of N*M, which may define locations of virtual elements, for example, as a convolution of locations of physical elements, e.g., the antennas 814 and/or 816.

In some demonstrative aspects, a radar system may include a plurality of radar devices 800. For example, vehicle 100 (FIG. 1) may include a plurality of radar devices 800, e.g., as described below.

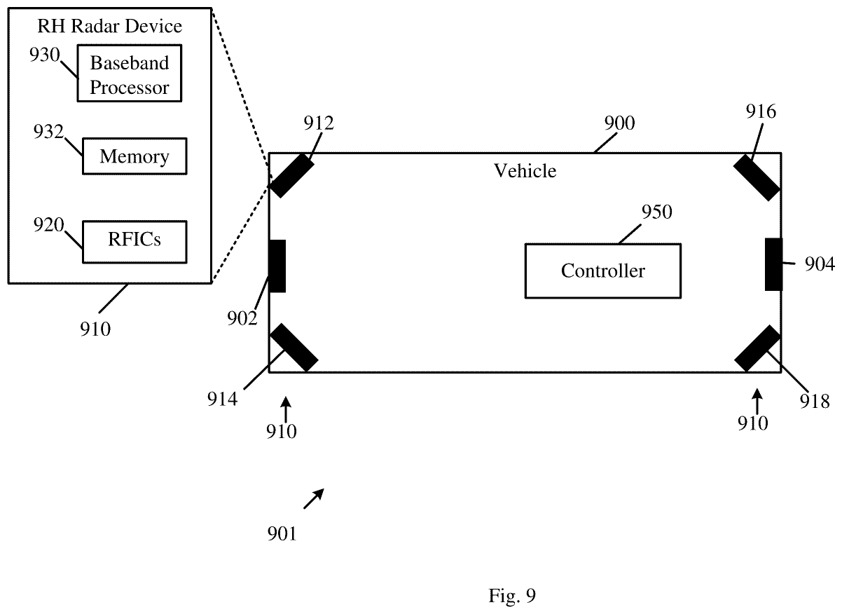

Reference is made to FIG. 9, which schematically illustrates a radar system 901 including a plurality of Radio Head (RH) radar devices (also referred to as RHs) 910 implemented in a vehicle 900, in accordance with some demonstrative aspects.

In some demonstrative aspects, as shown in FIG. 9, the plurality of RH radar devices 910 may be located, for example, at a plurality of positions around vehicle 900, for example, to provide radar sensing at a large field of view around vehicle 900, e.g., as described below.

In some demonstrative aspects, as shown in FIG. 9, the plurality of RH radar devices 910 may include, for example, six RH radar devices 910, e.g., as described below.

In some demonstrative aspects, the plurality of RH radar devices 910 may be located, for example, at a plurality of positions around vehicle 900, which may be configured to support 360-degrees radar sensing, e.g., a field of view of 360 degrees surrounding the vehicle 900, e.g., as described below.

In one example, the 360-degrees radar sensing may allow to provide a radar-based view of substantially all surroundings around vehicle 900, e.g., as described below.

In other aspects, the plurality of RH radar devices 910 may include any other number of RH radar devices 910, e.g., less than six radar devices or more than six radar devices.

In other aspects, the plurality of RH radar devices 910 may be positioned at any other locations and/or according to any other arrangement, which may support radar sensing at any other field of view around vehicle 900, e.g., 360-degrees radar sensing or radar sensing of any other field of view.

In some demonstrative aspects, as shown in FIG. 9, vehicle 900 may include a first RH radar device 902, e.g., a front RH, at a front-side of vehicle 900.

In some demonstrative aspects, as shown in FIG. 9, vehicle 900 may include a second RH radar device 904, e.g., a back RH, at a back-side of vehicle 900.

In some demonstrative aspects, as shown in FIG. 9, vehicle 900 may include one or more of RH radar devices at one or more respective corners of vehicle 900. For example, vehicle 900 may include a first corner RH radar device 912 at a first corner of vehicle 900, a second corner RH radar device 914 at a second corner of vehicle 900, a third corner RH radar device 916 at a third corner of vehicle 900, and/or a fourth corner RH radar device 918 at a fourth corner of vehicle 900.

In some demonstrative aspects, vehicle 900 may include one, some, or all, of the plurality of RH radar devices 910 shown in FIG. 9. For example, vehicle 900 may include the front RH radar device 902 and/or back RH radar device 904.

In other aspects, vehicle 900 may include any other additional or alternative radar devices, for example, at any other additional or alternative positions around vehicle 900. In one example, vehicle 900 may include a side radar, e.g., on a side of vehicle 900.

In some demonstrative aspects, as shown in FIG. 9, vehicle 900 may include a radar system controller 950 configured to control one or more, e.g., some or all, of the RH radar devices 910.

In some demonstrative aspects, at least part of the functionality of radar system controller 950 may be implemented by a dedicated controller, e.g., a dedicated system controller or central controller, which may be separate from the RH radar devices 910, and may be configured to control some or all of the RH radar devices 910.

In some demonstrative aspects, at least part of the functionality of radar system controller 950 may be implemented as part of at least one RH radar device 910.

In some demonstrative aspects, at least part of the functionality of radar system controller 950 may be implemented by a radar processor of an RH radar device 910. For example, radar processor 834 (FIG. 8) may include one or more elements of radar system controller 950, and/or may perform one or more operations and/or functionalities of radar system controller 950.

In some demonstrative aspects, at least part of the functionality of radar system controller 950 may be implemented by a system controller of vehicle 900. For example, vehicle controller 108 (FIG. 1) may include one or more elements of radar system controller 950, and/or may perform one or more operations and/or functionalities of radar system controller 950.

In other aspects, one or more functionalities of system controller 950 may be implemented as part of any other element of vehicle 900.

In some demonstrative aspects, as shown in FIG. 9, an RH radar device 910 of the plurality of RH radar devices 910, may include a baseband processor 930 (also referred to as a “Baseband Processing Unit (BPU)”), which may be configured to control communication of radar signals by the RH radar device 910, and/or to process radar signals communicated by the RH radar device 910. For example, baseband processor 930 may include one or more elements of radar processor 834 (FIG. 8), and/or may perform one or more operations and/or functionalities of radar processor 834 (FIG. 8).

In other aspects, an RH radar device 910 of the plurality of RH radar devices 910 may exclude one or more, e.g., some or all, functionalities of baseband processor 930. For example, controller 950 may be configured to perform one or more, e.g., some or all, functionalities of the baseband processor 930 for the RH.

In one example, controller 950 may be configured to perform baseband processing for all RH radar devices 910, and all RH radio devices 910 may be implemented without baseband processors 930.

In another example, controller 950 may be configured to perform baseband processing for one or more first RH radar devices 910, and the one or more first RH radio devices 910 may be implemented without baseband processors 930; and/or one or more second RH radar devices 910 may be implemented with one or more functionalities, e.g., some or all functionalities, of baseband processors 930.

In another example, one or more, e.g., some or all, RH radar devices 910 may be implemented with one or more functionalities, e.g., partial functionalities or full functionalities, of baseband processors 930.

In some demonstrative aspects, baseband processor 930 may include one or more components and/or elements configured for digital processing of radar signals communicated by the RH radar device 910, e.g., as described below.

In some demonstrative aspects, baseband processor 930 may include one or more FFT engines, matrix multiplication engines, DSP processors, and/or any other additional or alternative baseband, e.g., digital, processing components.

In some demonstrative aspects, as shown in FIG. 9, RH radar device 910 may include a memory 932, which may be configured to store data processed by, and/or to be processed by, baseband processor 930. For example, memory 932 may include one or more elements of memory 838 (FIG. 8), and/or may perform one or more operations and/or functionalities of memory 838 (FIG. 8).

In some demonstrative aspects, memory 932 may include an internal memory, and/or an interface to one or more external memories, e.g., an external Double Data Rate (DDR) memory, and/or any other type of memory.

In other aspects, an RH radar device 910 of the plurality of RH radar devices 910 may exclude memory 932. For example, the RH radar device 910 may be configured to provide radar data to controller 950, e.g., in the form of raw radar data.

In some demonstrative aspects, as shown in FIG. 9, RH radar device 910 may include one or more RF units, e.g., in the form of one or more RF Integrated Chips (RFICs) 920, which may be configured to communicate radar signals, e.g., as described below.

For example, an RFIC 920 may include one or more elements of front-end 804 (FIG. 8), and/or may perform one or more operations and/or functionalities of front-end 804 (FIG. 8).

In some demonstrative aspects, the plurality of RFICs 920 may be operable to form a radar antenna array including one or more Tx antenna arrays and one or more Rx antenna arrays.

For example, the plurality of RFICs 920 may be operable to form MIMO radar antenna 881 (FIG. 8) including Tx arrays 824 (FIG. 8), and/or Rx arrays 826 (FIG. 8).

Referring back to FIG. 8, in some demonstrative aspects, an RF chain, for example, a radar Rx chain 812 and/or a radar Tx chain 810, may include an Amplifier-Oscillator (AMP-OSC) 898, e.g., as described below.

In one example, each radar Rx chain 812 and/or each radar Tx chain 810 may include an AMP-OSC 898.

In another example, an AMP-OSC 898 may be configured to serve a plurality of RF chains, e.g., including one or more Rx chains and/or one or more Tx chains.

In some demonstrative aspects, the AMP-OSC 898 may be switchable between an amplifying mode and an oscillating mode, for example, based on a control input, e.g., as described below.

In some demonstrative aspects, the AMP-OSC 898 may be configured to provide an amplified signal at the amplifying mode, for example, by amplifying an input signal, e.g., as described below.

In some demonstrative aspects, the AMP-OSC 898 may be configured to generate an oscillating signal at the oscillating mode, e.g., as described below.

In some demonstrative aspects, the input signal may be based on a Local oscillator (LO) signal from an external oscillator source, a Phase-Locked Loop (PLL) circuit or the like (not shown in FIG. 8), e.g., as described below.

In some demonstrative aspects, an LO, e.g., a single LO source, may be implemented to generate the LO signal, for example, externally to an RF chain, for example, in implementations where a total number of Tx elements and/or Rx elements in an array is too high to be accommodated in a single RF chip.

In some demonstrative aspects, a device implementing a digital phased array system, e.g., radar device 800, may utilize a complex LO distribution network. For example, the LO distribution network may distribute an LO signal to a plurality of RF chains, e.g., all RF chains. For example, radar device 800 may utilize the LO distribution network to distribute the LO signal to the plurality of Tx chains 810 and/or the plurality of Rx chains 812, for example, to maintain coherency of array elements of radar device 800.

In some demonstrative aspects, the AMP-OSC 898 may be configured to provide a technical solution to support a self-test, e.g., an in-field self-test, an end-of-line self-test, and/or any other type of self-test, of an RF chain including the AMP-OSC 898, e.g., as described below.

For example, an AMP-OSC 898 in a radar Rx chain 812 may be configured to provide a technical solution to support a self-test of the radar Rx chain 812, e.g., as described below.

For example, an AMP-OSC 898 in a radar Tx chain 810 may be configured to provide a technical solution to support a self-test of the radar Tx chain 810, e.g., as described below.

In some demonstrative aspects, the AMP-OSC 898 may be configured to provide a technical solution to support a self-test of an Rx chip, e.g., an Rx chip 883 including one or more Rx chains 812, for example, in implementations where Tx signals, which are to be received by the Rx chip, may be generated externally to the Rx chip, e.g., as described below.

In one example, an Rx chip may not support a self-test, e.g., in a standalone configuration, when an external Tx signal to be received by the Rx chip is generated externally to the Rx chip. For example, the Rx chip may be required to utilize the external Tx signal during a self-testing and/or verification procedure, for example, to support a test signal for the entire Rx chain. According to this example, testing and/or verification of the Rx chip, e.g., on a production floor and/or during an in-the-field self-test, may become complex and/or expensive.

In some demonstrative aspects, there may be one or more technical problems, disadvantages, and/or inefficiencies in implementing a local Tx signal for an Rx chip, e.g., for each Rx chain of the Rx chip, for example, to support a self-test in a standalone configuration of the Rx chip.

In one example, this implementation of the local Tx signal may be bulky and/or may require additional silicon area, which may increase a total product cost, for example, for supporting testing and measurements, which may not actually be part of the operational mode of the product.

In some demonstrative aspects, the AMP-OSC 898 may be configured to implement a circuitry topology, which may be configured to provide a technical solution to support conversion of an amplifier functionality, e.g., of an RF amplifier, an mmWave amplifier or any other type of amplifier, into an oscillator functionality, for example, even without substantially increasing silicon size, e.g., as described below.

In some demonstrative aspects, the AMP-OSC 898 may be configured to provide a technical solution to support conversion of an amplifier functionality of an amplifier, e.g., an LNA, into an oscillator functionality. For example, the AMP-OSC 898 may be implemented by substantially any Rx chain, which may include at least one LNA.

In some demonstrative aspects, the AMP-OSC 898 may be controllably operated at a first configuration, e.g., an amplifier configuration, to provide a technical solution to support an amplifying mode, for example, to amplify a received signal, for example, at a normal operation mode, e.g., as described below.

In some demonstrative aspects, the AMP-OSC 898 may be controllably operated at a second configuration, e.g., an oscillator configuration, to provide a technical solution to support an oscillating mode, for example, to support self-tests and/or measurements of an Rx chain including the AMP-OSC 898, e.g., for validating the Rx chip in a standalone mode, e.g., as described below.

In some demonstrative aspects, the AMP-OSC 898 may be configured to provide a technical solution to support a robust design with acceptable, e.g., exceptional, stability as an amplifier, for example, at the amplifying mode, e.g., as described below.

In some demonstrative aspects, the AMP-OSC 898 may be controllably switched, for example, between a low noise amplification mode and an oscillator mode, e.g., as described below.

In some demonstrative aspects, the AMP-OSC 898 may be controllably operated at the low noise amplification mode, for example, at a normal operation mode of the Rx chip, e.g., as described below.

In some demonstrative aspects, the AMP-OSC 898 may be controllably operated at the oscillator mode, for example, in order to generate a local signal to test other blocks of the Rx chain, for example, one or more next stages of the LNA, a mixer, BB amplifiers, BB filters, and/or any other Rx components, e.g., for validating the Rx chip in a standalone mode.

In some demonstrative aspects, the AMP-OSC 898 may be configured to provide a technical solution to support a self-test of an RF chip, for example, in implementations where an LO signal for the RF chip is generated externally to the RF chip, e.g., as described below.

In one example, an RF chip may not support a self-test, e.g., in a standalone configuration, when an LO signal is generated externally to the RF chip. For example, the RF chip may be required to utilize the external LO signal during a testing and/or verification procedure, for example, to support up-conversion and/or down-conversion, and/or as a reference clock for a DAC operation and/or an ADC operation. According to this example, testing and/or verification of the RF chip, e.g., on a production floor and/or during a self-test, may become complex and/or expensive.

In some demonstrative aspects, there may be one or more technical problems, disadvantages, and/or inefficiencies in implementing a local LO for an RF chip, e.g., for each RF chain, for example, within the RF chip or at an interface of an LO distribution network, for example, to support a self-test in a standalone configuration of the RF chip.

In one example, this implementation of the local LO may be bulky and/or may require additional silicon area, which may increase a total product cost, for example, for supporting testing and measurements, which may not actually be part of the operational mode of the product.

In some demonstrative aspects, the AMP-OSC 898 may be configured to implement a circuitry topology, which may be configured to provide a technical solution to support conversion of an amplifier functionality, e.g., of an RF amplifier, an mmWave amplifier or any other type of amplifier, into an oscillator functionality, for example, even without substantially increasing silicon size, e.g., as described below.

In some demonstrative aspects, the AMP-OSC 898 may be configured to provide a technical solution to support conversion of an amplifier functionality of an amplifier, e.g., any amplifier, of an LO distribution network, for example, into an oscillator functionality. For example, the AMP-OSC 898 may be implemented by substantially any suitable LO distribution network of a system including multi Tx elements and/or Rx elements, which may include at least one amplifier.

In some demonstrative aspects, the AMP-OSC 898 may be configured to provide a technical solution to support an amplifying mode, for example, to drive an external LO signal to one or more RF chains, for example, all RF chains connected to the LO distribution network, e.g., at a normal operation mode.

In some demonstrative aspects, the AMP-OSC 898 may be configured to provide a technical solution to support an oscillating mode, for example, to support self-tests and/or measurements of an RF chip including the AMP-OSC 898, e.g., for validating the RF chip in a standalone mode.

In some demonstrative aspects, the AMP-OSC 898 may be configured to provide a technical solution to support a robust design with acceptable, e.g., exceptional, stability as an amplifier, for example, at the amplifying mode, e.g., as described below.

In one example, due to stability issues, a tendency of amplifiers to oscillate may be used responsibly, for example, as this tendency may result in a degraded, or even unacceptable, amplification performance and/or oscillation performance.

In some demonstrative aspects, the AMP-OSC 898 may be configured to provide a technical solution to support a compact oscillator, e.g., at the oscillating mode, for example, by configuring the oscillator to use one or more amplifier components. Accordingly, the oscillator functionality may not require substantial additional silicon area.

In some demonstrative aspects, the AMP-OSC 898 may be configured to provide a technical solution to support a compact design and/or a smooth transition between the amplifying mode and the oscillating mode, e.g., as described below.

In some demonstrative aspects, the AMP-OSC 898 may be configured to support the transition between the amplifying mode and the oscillating mode, for example, based on toggling of one or more switches, which may be implemented, for example, by relatively small switches. Accordingly, the oscillating mode may be implemented with substantially no additional area, e.g., as the area used for the oscillating mode may be substantially the same area that is utilized by the amplifier.

In some demonstrative aspects, the AMP-OSC 898 may be configured to utilize switches, for example, to support a technical solution to support configuration of the oscillating mode, for example, by configuring inductances of an output transformer of the AMP-OSC 898, for example, even without substantially increasing a physical size of the AMP-OSC 898, e.g., as described below.

In some demonstrative aspects, the AMP-OSC 898 may be configured to provide a technical solution to support a full verification flow, for example, including a self-test of an RF chip, e.g., at any given time and/or with a minimum power consumption.

In some demonstrative aspects, the AMP-OSC 898 may be configured to provide a technical solution to support compliance of automotive grade components of an automotive radar system, e.g., radar device 800, which may utilize an external LO signal provided to RF chips of the automotive radar system, for example, with lower costs on the production floor, and/or when the radar system is already installed on vehicles.

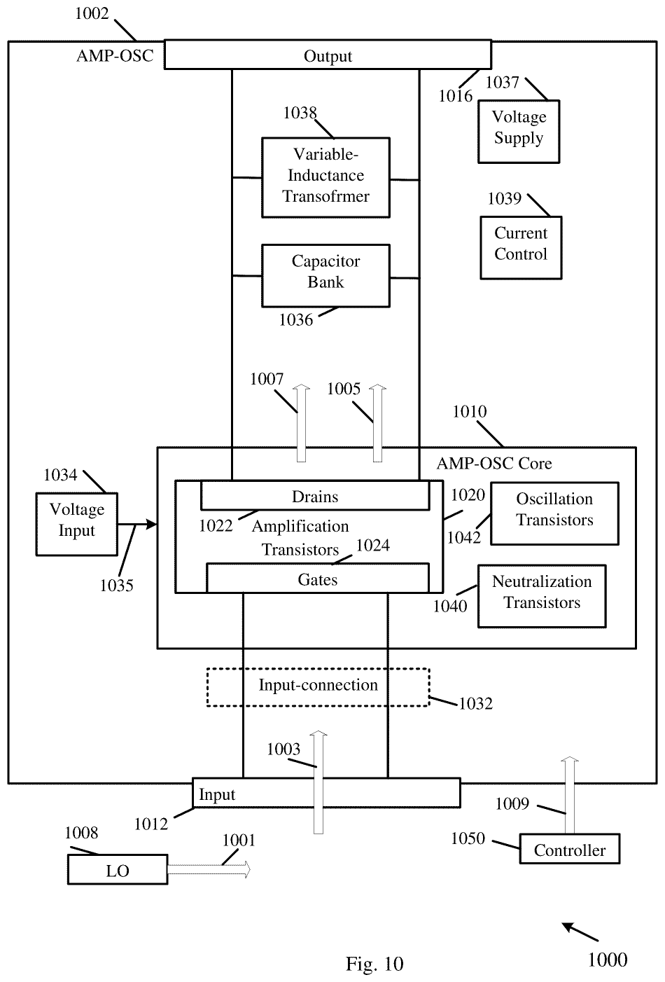

Reference is made to FIG. 10, which schematically illustrates an apparatus 1000 including an AMP-OSC 1002, in accordance with some demonstrative aspects.

In some demonstrative aspects, one or more components of apparatus 1000 may be implemented as part of a radar device. For example, radar device 800 (FIG. 8) may include one or more element of apparatus 1000, and/or may perform one or more operations and/or functionalities of apparatus 1000.

In some demonstrative aspects, apparatus 1000 may be implemented as part of any other suitable device and/or system.

For example, in some demonstrative aspects, apparatus 1000 may be implemented as part of a device, for example, a mobile device, a computing device, and/or a wireless communication device, for example, to communicate RF wireless communication signals.

For example, in some demonstrative aspects, apparatus 1000 may be implemented to communicate the RF wireless communication signals over millimeter wave (mmWave) frequencies and/or any other suitable frequencies.

In some demonstrative aspects, AMP-OSC 1002 may be switchable between an amplifying mode and an oscillating mode, for example, based on a control input 1009, e.g., as described below.

In some demonstrative aspects, AMP-OSC 1002 may be implemented as part of an RF chain and/or an LO chain, e.g., as described below.

In one example, a radar Rx chain 812 (FIG. 8) and/or a radar Tx chain 810 (FIG. 8) may include AMP-OSC 1002.

In some demonstrative aspects, AMP-OSC 1002 may include an input terminal 1012, e.g., as described below.

In some demonstrative aspects, AMP-OSC 1002 may include an output terminal 1016, e.g., as described below.

In some demonstrative aspects, AMP-OSC 1002 may include an AMP-OSC core 1010 connected between the input terminal 1012 and the output terminal 1016, e.g., as described below.

In some demonstrative aspects, the AMP-OSC core 1010 may be operable at an amplification core-mode, for example, based on a first setting of the control input 1009 corresponding to the amplifying mode, e.g., as described below.

In some demonstrative aspects, the AMP-OSC core 1010 may be operable at an oscillation core-mode, for example, based on a second setting of the control input 1009 corresponding to the oscillating mode, e.g., as described below.

In some demonstrative aspects, the AMP-OSC core 1010 may be configured to provide an amplified signal 1005 to the output terminal 1016, for example, at the amplification core-mode, for example, by amplifying an input signal 1003 from the input terminal 1012, e.g., as described below.

In some demonstrative aspects, the AMP-OSC core 1010 may be configured to generate an oscillating signal 1007, and to provide the oscillating signal 1007 to the output terminal 1016, for example, at the oscillation core-mode, e.g., as described below.

In some demonstrative aspects, apparatus 1000 may include a controller 1050, which may be configured to provide the control input 1009, for example, to control setting of the AMP-OSC 1002 at the amplifying mode or at the oscillating mode, e.g., as described below.

In some demonstrative aspects, controller 1050 may be configured to controllably configure the control input 1009, for example, based on an operation mode to be set for the AMP-OSC 1002, e.g., as described below.

In some demonstrative aspects, controller 1050 may be configured to controllably configure the first setting of the control input 1009, for example, when AMP-OSC core 1010 is to be operated at the amplification core-mode, e.g., as described below.

In some demonstrative aspects, controller 1050 may be configured to controllably configure the second setting of the control input 1009, for example, when AMP-OSC core 1010 is to be operated at the oscillating core-mode, e.g., as described below.

In some demonstrative aspects, controller 1050 may be configured to controllably configure the second setting of the control input 1009, for example, to support a self-test, e.g., an in-field self-test, an end-of-line self-test, and/or any other type of self-test, of an RF chain including the AMP-OSC 1002, e.g., as described above.

For example, controller 1050 may be configured to controllably configure the second setting of the control input 1009, for example, to support a self-test of a radar Rx chain including the AMP-OSC 1002, e.g., as described above.

For example, controller 1050 may be configured to controllably configure the second setting of the control input 1009, for example, to support a self-test of a radar Tx chain including the AMP-OSC 1002, e.g., as described above.

In some demonstrative aspects, controller 1050 may be configured to provide the second setting of the control input 1009, for example, at a test mode, for example, to test an RF chain including the AMP-OSC 1002, e.g., as described below.

In some demonstrative aspects, the input signal 1003 may be based on an LO signal 1001, e.g., as described below.

In some demonstrative aspects, system 1000 may include an LO 1008, for example, to generate the LO signal 1001, e.g., as described below.

In some demonstrative aspects, the AMP-OSC core 1010 may include a differential pair of amplification transistors 1020, e.g., as described below.

In some demonstrative aspects, the differential pair of amplification transistors 1020 may be configured to provide the amplified signal 1005 to the output terminal 1016, for example, by amplifying the input signal 1003 from the input terminal 1012 at the amplification core-mode, e.g., as described below.

In some demonstrative aspects, drains 1022 of the differential pair of amplification transistors 1020 may be connected to the output terminal 1016, e.g., as described below.

In some demonstrative aspects, the differential pair of amplification transistors 1020 may be connected to the input terminal 1012, e.g., as described below.

In some demonstrative aspects, the differential pair of amplification transistors 1020 may be disconnected from the input terminal 1012, for example, at the oscillation core-mode, e.g., as described below.

In other aspects, the differential pair of amplification transistors 1020 may remain connected to the input terminal 1012, for example, at the oscillation core-mode, e.g., as described below.

In some demonstrative aspects, gates 1024 of the differential pair of amplification transistors 1020 may be connected to the input terminal 1012, for example, at the amplification core-mode, e.g., as described below.

In some demonstrative aspects, gates 1024 of the differential pair of amplification transistors 1020 may be disconnected from the input terminal 1012, for example, at the oscillation core-mode, e.g., as described below.

In other aspects, the gates 1024 of the differential pair of amplification transistors 1020 may remain connected to the input terminal 1012, for example, at the oscillation core-mode, e.g., as described below.

In some demonstrative aspects, the AMP-OSC core 1010 may include voltage input circuitry 1034, which may be controllable to connect a bias voltage 1035 to the AMP-OSC core 1010, for example, at the amplification core-mode, e.g., as described below.

In some demonstrative aspects, voltage input circuitry 1034 may be controllable to disconnect the bias voltage 1035 from the AMP-OSC core 1010, for example, at the oscillation core-mode, e.g., as described below.

In some demonstrative aspects, AMP-OSC 1002 may be configured to set an oscillation-frequency of the oscillating signal 1007 at the oscillating mode, for example, based on the second setting of the control input 1009, e.g., as described below.

In some demonstrative aspects, AMP-OSC 1002 may be configured to set the oscillation-frequency of the oscillating signal 1007 at the oscillating mode, for example, based on an oscillation-configuration setting in the second setting of the control input 1009, e.g., as described below.

In some demonstrative aspects, AMP-OSC 1002 may be configured to set a first oscillation-frequency of the oscillating signal 1007, for example, based on a first oscillation-configuration setting in the second setting of the control input 1009, e.g., as described below.

In some demonstrative aspects, AMP-OSC 1002 may be configured to set a second oscillation-frequency of the oscillating signal 1007, for example, based on a second oscillation-configuration setting in the second setting of the control input 1009, e.g., as described below.

In some demonstrative aspects, the first oscillation-configuration setting may be different from the second oscillation-configuration setting, e.g., as described below.

In some demonstrative aspects, the first oscillation frequency may be different from the second oscillation frequency, e.g., as described below.

In some demonstrative aspects, AMP-OSC 1002 may include a capacitor bank 1036 including a plurality of capacitors, e.g., as described below.

In some demonstrative aspects, the capacitor bank 1036 may be controllable to connect one or more capacitors of the capacitor bank 1036 to AMP-OSC core 1010, for example, based on the oscillation-configuration setting to set the oscillation-frequency of the oscillating signal 1007 at the oscillating mode, e.g., as described below.

In some demonstrative aspects, AMP-OSC 1002 may include voltage supply circuitry 1037, which may be controllable to supply a first voltage to the AMP-OSC core 1010, for example, at the amplification core-mode, e.g., as described below.

In some demonstrative aspects, voltage supply circuitry 1037 may be controllable to supply a second voltage to the AMP-OSC core 1010, for example, at the oscillation core-mode, e.g., as described below.

In some demonstrative aspects, the first voltage may be different from the second voltage, e.g., as described below.

In some demonstrative aspects, the voltage supply circuitry 1037 may include a voltage-supply switch (not shown in FIG. 1), which may be controllable to switch between the first voltage and the second voltage, e.g., as described below.

In some demonstrative aspects, the voltage supply circuitry 1037 may include a variable voltage supplier (not shown in FIG. 1), which may be configured to supply a voltage, e.g., the first voltage or the second voltage, to the AMP-OSC core 1010, for example, based on the control input 1009, e.g., as described below.

In some demonstrative aspects, AMP-OSC 1002 may include current control circuitry 1039, which may be configured to set a first current for the AMP-OSC core 1010, for example, at the amplification core-mode, e.g., as described below.

In some demonstrative aspects, current control circuitry 1039 may be configured to set a second current for the AMP-OSC core 1010, for example, at the oscillation core-mode, e.g., as described below.

In some demonstrative aspects, the first current may be different from the second current, e.g., as described below.

In some demonstrative aspects, current control circuitry 1039 may include a variable current source (not shown in FIG. 1), which may be configured to generate the first current and the second current, e.g., as described below.

In some demonstrative aspects, current control circuitry 1039 may include a capacitor (not shown in FIG. 1), which may be connected in parallel to the variable current source, e.g., as described below.

In some demonstrative aspects, AMP-OSC 1002 may include a variable-inductance transformer 1038 connected between AMP-OSC core 1010 and the output terminal 1016, e.g., as described below.

In some demonstrative aspects, an inductance of the variable-inductance transformer 1038 may be configurable, for example, based on the second setting of the control signal 1009 at the oscillating mode, e.g., as described below.

In some demonstrative aspects, the inductance of the variable-inductance transformer 1038 may be configurable, for example, based on the oscillation-configuration setting in the second setting of the control input 1009 to set the oscillation-frequency of the oscillating signal 1007 at the oscillating mode, e.g., as described below.

In some demonstrative aspects, AMP-OSC 1002 may be configured to set a first inductance of the variable-inductance transformer 1038, for example, based on a first oscillation-configuration setting in the second setting of the control input 1009, e.g., as described below.

In some demonstrative aspects, AMP-OSC 1002 may be configured to set a second inductance of the variable-inductance transformer 1038, for example, based on a second oscillation-configuration setting in the second setting of the control input 1009, e.g., as described below.

In some demonstrative aspects, the first inductance may be different from the second inductance, e.g., as described below.

In some demonstrative aspects, the first oscillation-configuration setting may be different from the second oscillation-configuration setting, e.g., as described below.

In some demonstrative aspects, the variable-inductance transformer 1038 may include a three-way (3-way) transformer including a first inductor (not shown in FIG. 10) connected to AMP-OSC core 1010, a second inductor (not shown in FIG. 10) coupled to the first inductor to provide the oscillating signal 1007 to the output terminal 1016, and a third inductor (not shown in FIG. 10) coupled to the first inductor and to the second inductor, e.g., as described below.

In some demonstrative aspects, the third inductor may be connected to a variable load (not shown in FIG. 10), which may be configurable, for example, based on the oscillation-configuration setting, e.g., as described below.

In some demonstrative aspects, the variable-inductance transformer 1038 may include a switchable winding (not shown in FIG. 10) including a plurality of turns, e.g., as described below.

In some demonstrative aspects, the switchable winding may be controllable to connect one or more turns of the plurality of turns between AMP-OSC core 1010 and the output terminal 1016, for example, based on the oscillation-configuration setting, e.g., as described below.

In some demonstrative aspects, the plurality of turns of the switchable winding (not shown in FIG. 10) may include a first turn and a second turn, e.g., as described below.

In some demonstrative aspects, the first turn of the switchable winding (not shown in FIG. 10) may be connected between the AMP-OSC core 1010 and the output terminal 1016, e.g., as described below.

In some demonstrative aspects, the switchable winding may include winding switching circuitry (not shown in FIG. 10), which may be controllable to connect the second turn in parallel to the first turn, for example, at the oscillation core mode, e.g., as described below.

In some demonstrative aspects, the winding switching circuitry (not shown in FIG. 10) may be controllable to disconnect the second turn from the first turn, for example, at the amplification core-mode, e.g., as described below.

In some demonstrative aspects, AMP-OSC 1002 may include input-connection circuitry 1032 connected between the input terminal 1012 and AMP-OSC core 1010, e.g., as described below.

In some demonstrative aspects, the input-connection circuitry 1032 may be controllable to connect AMP-OSC core 1010 to the input terminal 1012 or to disconnect AMP-OSC core 1010 from the input terminal 1012, for example, based on the oscillation-configuration setting to set the oscillation-frequency of the oscillating signal 1007 at the oscillating mode, e.g., as described below.

In some demonstrative aspects, the input-connection circuitry 1032 may be controllable to connect AMP-OSC core 1010 to the input terminal 1012, for example, to amplify the input signal 1003 from the input terminal 1012, for example, based on the first setting of the control input 1009, e.g., as described below.

In some demonstrative aspects, the input-connection circuitry 1032 may be controllable to disconnect AMP-OSC core 1010 from the input terminal 1012, for example, based on the second setting of the control input 1009, e.g., as described below.

In some demonstrative aspects, the input-connection circuitry 1032 may include a pair of input-switches (not shown in FIG. 10) connected between the input terminal 1012 and AMP-OSC core 1010, e.g., as described below.

In other aspects, the AMP-OSC core 1010 may remain connected to the input terminal 1012, for example, at the oscillation core-mode, e.g., as described below. According to these aspects, the input-connection circuitry 1032 may be potentially omitted.

In some demonstrative aspects, the AMP-OSC core 1010 may include a pair of neutralization transistors 1040, e.g., as described below.

In some demonstrative aspects, the pair of neutralization transistors 1040 may be configured to neutralize a parasitic capacitance of the differential pair of amplification transistors 1020, for example, at the amplification core-mode, e.g., as described below.

In some demonstrative aspects, the pair of neutralization transistors 1040 may be configured to cross-couple connect the differential pair of amplification transistors 1020, for example, at the oscillation core-mode, e.g., as described below.

In some demonstrative aspects, the pair of neutralization transistors 1040 may be controllable to be at a transistor-off state, for example, to neutralize the parasitic capacitance of the differential pair of amplification transistors 1020 at the amplification core-mode, e.g., as described below.

In some demonstrative aspects, the pair of neutralization transistors 1040 may be controllable to be at a transistor-on state, for example, to cross-couple connect the differential pair of amplification transistors 1020 at the oscillation core-mode, e.g., as described below.

In some demonstrative aspects, AMP-OSC 1002 may implement an amplifier topology, which may utilize a neutralized differential common-source amplifier for amplification, e.g., for mm Wave amplification, e.g., as described below.

In some demonstrative aspects, the pair of neutralization transistors 1040 may be configured to neutralize a gate-drain parasitic capacitance of the differential pair of amplification transistors 1020, for example, to provide a technical solution to prevent any feedback between input terminal 1012 and output terminal 1016.

In some demonstrative aspects, the pair of neutralization transistors 1040 may be switched to become a short, for example, to cross-couple connect the input terminal 1012 and the output terminal 1016, e.g., with a proper phase. For example, this short may provide a positive feedback to the differential pair of amplification transistors 1020, which may trigger oscillations, for example, to generate the oscillating signal 1007.

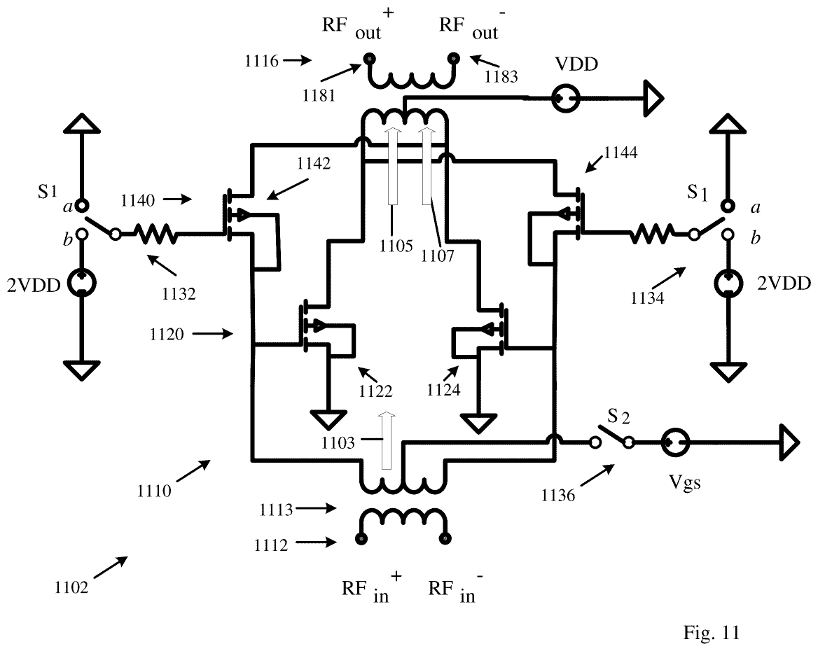

Reference is made to FIG. 11, which schematically illustrates an AMP-OSC 1102, in accordance with some demonstrative aspects. For example, AMP-OSC 1002 (FIG. 10) may include one or more elements of AMP-OSC 1102, and/or may perform one or more operations and/or functionalities of AMP-OSC 1102.

In some demonstrative aspects, as shown in FIG. 11, AMP-OSC 1102 may include an input terminal 1112.

In some demonstrative aspects, as shown in FIG. 11, AMP-OSC 1102 may include an output terminal 1116.

In some demonstrative aspects, as shown in FIG. 11, AMP-OSC 1102 may include an AMP-OSC core 1110 connected between the input terminal 1112 and the output terminal 1116. For example, AMP-OSC core 1010 (FIG. 10) may include one or more elements of AMP-OSC core 1110, and/or may perform one or more operations and/or functionalities of AMP-OSC core 1110.

In some demonstrative aspects, the AMP-OSC core 1110 may be configured to provide an amplified signal 1105 to the output terminal 1116, for example, at an amplification core-mode, for example, by amplifying an input signal 1103 from the input terminal 1112, e.g., as described below.

In some demonstrative aspects, the AMP-OSC core 1010 may be configured to generate an oscillating signal 1107, and to provide the oscillating signal 1107 to the output terminal 1116, for example, at an oscillation core-mode, e.g., as described below.

In some demonstrative aspects, as shown in FIG. 11, AMP-OSC core 1110 may include a differential pair of amplification transistors 1120, e.g., including a first amplification transistor 1122 and a second amplification transistor 1124.

In some demonstrative aspects, as shown in FIG. 11, the differential pair of amplification transistors 1120 may include a pair of N-channel Metal Oxide Semiconductor (NMOS) transistors, e.g., as described below.

In some demonstrative aspects, the differential pair of amplification transistors 1120 may include a pair of P-channel Metal Oxide Semiconductor (PMOS) transistors.

In other aspects, the differential pair of amplification transistors 1120 may include any other type of transistors.

In some demonstrative aspects, as shown in FIG. 11, AMP-OSC core 1110 may include a pair of neutralization transistors 1140, e.g., including a first neutralization transistor 1142 and a second neutralization transistor 1144.

In some demonstrative aspects, as shown in FIG. 11, the pair of neutralization transistors 1140 may include a pair of NMOS transistors, e.g., as described below.

In other aspects, the pair of neutralization transistors 1140 may include PMOS transistors, or any other type of transistors, e.g., as described below.

In some demonstrative aspects, the pair of neutralization transistors 1140 may be configured to neutralize a parasitic capacitance of the differential pair of amplification transistors 1120, for example, at the amplification core-mode of AMP-OSC core 1110, e.g., as described below.

In some demonstrative aspects, the pair of neutralization transistors 1140 may be configured to cross-couple connect the differential pair of amplification transistors 1120, for example, at the oscillation core-mode of AMP-OSC core 1110, e.g., as described below.

In some demonstrative aspects, the pair of neutralization transistors 1140 may be controllable to be at a transistor-off state, for example, to neutralize the parasitic capacitance of the differential pair of amplification transistors 1120, for example, at the amplification core-mode of the AMP-OSC core 1110, e.g., as described below.

In some demonstrative aspects, the pair of neutralization transistors 1140 may be controllable to be at a transistor-on state, for example, to cross-couple connect the differential pair of amplification transistors 1120, for example, at the oscillation core-mode of the AMP-OSC core 1110, e.g., as described below.

In some demonstrative aspects, as shown in FIG. 11, a drain of the first amplification transistor 1122 may be connected to a first differential output of the output terminal 1116, e.g., as described below.

In some demonstrative aspects, as shown in FIG. 11, a drain of the second amplification transistor 1124 may be connected to a second differential output of the output terminal 1116, e.g., as described below.

In some demonstrative aspects, as shown in FIG. 11, the first neutralization transistor 1142 may be connected between a gate of the first amplification transistor 1122 and the drain of the second amplification transistor 1124, e.g., as described below.

In some demonstrative aspects, as shown in FIG. 11, the second neutralization transistor 1144 may be connected between a gate of the second amplification transistor 1124 and the drain of the first amplification transistor 1122, e.g., as described below.

In some demonstrative aspects, one of a source or a drain of the first neutralization transistor 1142 may be connected to the gate of the first amplification transistor 1122, and another one of the source or the drain of the first neutralization transistor 1142 may be connected to the drain of the second amplification transistor 1124, e.g., as described below.

In some demonstrative aspects, one of a source or a drain of the second neutralization transistor 1144 may be connected to the gate of the second amplification transistor 1124, and another one of the source or the drain of the second neutralization transistor 1144 may be connected to the drain of the first amplification transistor 1122, e.g., as described below.

For example, as shown in FIG. 11, the source of the first neutralization transistor 1142 may be connected to the gate of the first amplification transistor 1122, and the drain of the first neutralization transistor 1142 may be connected to the drain of the second amplification transistor 1124.

In another example, the drain of the first neutralization transistor 1142 may be connected to the gate of the first amplification transistor 1122, and the source of the first neutralization transistor 1142 may be connected to the drain of the second amplification transistor 1124.

For example, as shown in FIG. 11, the source of the second neutralization transistor 1144 may be connected to the gate of the second amplification transistor 1124, and the drain of the second neutralization transistor 1144 may be connected to the drain of the first amplification transistor 1122, e.g., as described below.

In another example, the drain of the second neutralization transistor 1144 may be connected to the gate of the second amplification transistor 1124, and the source of the second neutralization transistor 1144 may be connected to the drain of the first amplification transistor 1122.

In some demonstrative aspects, connections between the pair of neutralization transistors 1140 and the differential pair of amplification transistors 1120 may be flipped, for example, without major impact on performance, for example, since the neutralization of the differential pair of amplification transistors 1120 may be based on a drain-source capacitance, which may be in parallel to a drain-gate capacitance and/or a gate-source capacitance of the differential pair of amplification transistors 1120.

For example, the connections between the pair of neutralization transistors 1140 and the differential pair of amplification transistors 1120 may be flipped, for example, such that drains of the pair of neutralization transistors 1140 may be connected to the drains of the pair of amplification transistors 1120, and sources of the pair of neutralization transistors 1140 may be connected to gates of the pair of amplification transistors; or such that sources of the pair of neutralization transistors 1140 may be connected to the drains of the differential pair of amplification transistors 1120, and drains of the pair of neutralization transistors 1140 may be connected to the gates of the differential pair of amplification transistors 1120. According to this example, PMOS transistors may be connected with their sources to a power supply, and/or NMOS transistors may be connected with their drains to the power supply.

In some demonstrative aspects, as shown in FIG. 11, AMP-OSC 1102 may include a pair of gate switches, denoted S1, e.g., including a first gate switch 1132 and a second gate switch 1134.

In some demonstrative aspects, as shown in FIG. 11, the pair of gate switches S1 may be controllable, e.g., by controller 1050 (FIG. 1), for example, to switch a bias voltage of gates of the pair of neutralization transistors 1140 between a first Direct Current (DC) voltage (a) and a second DC voltage (b), e.g., as described below.

In some demonstrative aspects, the first DC voltage (a) may be configured to set the pair of neutralization transistors 1140 at the transistor-on state, e.g., as described below.

In some demonstrative aspects, the second DC voltage (b) may be configured to set the pair of neutralization transistors 1140 at the transistor-off state, e.g., as described below.

In some demonstrative aspects, as shown in FIG. 11, the first DC voltage (a) may include a Ground voltage.

In some demonstrative aspects, as shown in FIG. 11, the second DC voltage (b) may be based on a voltage supply level (VDD), e.g., as described below.

In some demonstrative aspects, as shown in FIG. 11, the second DC voltage (a) may be two times the VDD.

In one example, the second DC voltage (a) may be set to at least two times the VDD, for example, such that the bias voltage of the pair of neutralization transistors 1140 may be high enough, for example, compared to a source voltage of sources of the pair of neutralization transistors 1140 and a drain voltage of drains of the pair of neutralization transistors 1140. For example, the second DC voltage (a) may be set to at least two times the VDD to provide a low on-resistance of the pair of neutralization transistors 1140.

For example, the bias voltage of the pair of neutralization transistors 1140 may be based on a higher power than the VDD voltage, for example, as the drains of the pair of neutralization transistors 1140 are connected to the power supply voltage VDD. According to this example, suitable dedicated circuitry, or an additional power supply may be implemented to provide this bias voltage.

In some demonstrative aspects, as shown in FIG. 11, AMP-OSC 1102 may include voltage input circuitry 1136, which may be controllable, e.g., by controller 1050 (FIG. 1), to connect a bias voltage (Vgs) to gates of the differential pair of amplification transistors 1120, for example, at the amplification core-mode of AMP-OSC core 1110.

In some demonstrative aspects, as shown in FIG. 11, voltage input circuitry 1136 may be controllable e.g., by controller 1050 (FIG. 1), to disconnect the bias voltage Vgs from the gates of the differential pair of amplification transistors 1120, for example, at the oscillation core-mode of AMP-OSC core 1110.

In some demonstrative aspects, as shown in FIG. 11, voltage input circuitry 1136 may include a switch, denoted S2, which may be controllable e.g., by controller 1050 (FIG. 1), to disconnect the bias voltage Vgs from the gates of the differential pair of amplification transistors 1120, for example, at the oscillation core-mode of AMP-OSC core 1110.

In some demonstrative aspects, as shown in FIG. 11, AMP-OSC 1002 may include an input transformer 1113 connected between input terminal 1112 and the AMP-OSC core 1110.

In some demonstrative aspects, the input signal 1103 may not be present and a primary side, e.g., on the input terminal 1112, of the input transformer 1113 may be open, for example, at the oscillation core-mode of AMP-OSC core 1110.

In some demonstrative aspects, the pair of neutralization transistors 1140 may be turned on, and input terminal 1112 and input transformer 1113 may be connected to the AMP-OSC core 1110, for example, at the oscillating mode. For example, this configuration may increase a frequency of oscillation of the oscillating signal 1107.

In some demonstrative aspects, as shown in FIG. 11, an AMP-OSC core, e.g., AMP-OSC core 1120, may be implemented with a pair of neutralization transistors 1140 including a pair of NMOS transistors, e.g., as described above.

In other aspects, an AMP-OSC core may be implemented with a pair of neutralization transistors including a pair of PMOS transistors, e.g., as described below.

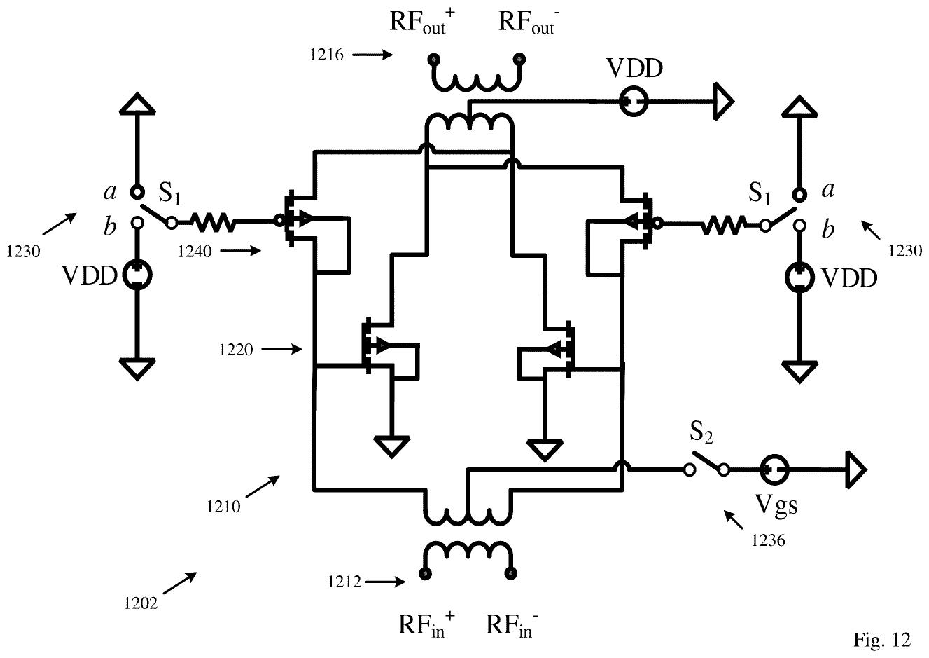

Reference is made to FIG. 12, which schematically illustrates an AMP-OSC 1202, in accordance with some demonstrative aspects. For example, AMP-OSC 1002 (FIG. 10) may include one or more elements of AMP-OSC 1202, and/or may perform one or more operations and/or functionalities of AMP-OSC 1202.

In some demonstrative aspects, as shown in FIG. 12, AMP-OSC 1202 may include an input terminal 1212, and an output terminal 1216.

In some demonstrative aspects, as shown in FIG. 12, AMP-OSC 1202 may include an AMP-OSC core 1210 connected between the input terminal 1212 and the output terminal 1216. For example, AMP-OSC core 1010 (FIG. 10) may include one or more elements of AMP-OSC core 1210, and/or may perform one or more operations and/or functionalities of AMP-OSC core 1210.

In some demonstrative aspects, as shown in FIG. 12, AMP-OSC core 1210 may include a differential pair of amplification transistors 1220, for example, including a pair of NMOS transistors.

In some demonstrative aspects, as shown in FIG. 12, AMP-OSC core 1210 may include a pair of neutralization transistors 1240.

In some demonstrative aspects, as shown in FIG. 12, the pair of neutralization transistors 1240 may include a pair of PMOS transistors 1240, e.g., as described below.

In other aspects, the pair of neutralization transistors may include any other type of transistors.

In one example, AMP-OSC 1202 may be configured similar to AMP-OSC 1102 (FIG. 11), for example, while including the pair of PMOS transistors 1240 as neutralization transistors, for example, instead of the pair of NMOS neutralization transistors 1140 (FIG. 11).

In some demonstrative aspects, as shown in FIG. 12, AMP-OSC 1202 may include a pair of gate switches 1230.

In some demonstrative aspects, as shown in FIG. 12, the pair of gate switches 1230 may be controllable, e.g., by controller 1050 (FIG. 1), to switch a bias voltage of gates of the pair of neutralization transistors 1240, for example, between a first DC voltage (a) and a second DC voltage (b).

In some demonstrative aspects, the first DC voltage (a) may be configured to set the pair of neutralization transistors 1240 at the transistor-on state, e.g., as described below.

In some demonstrative aspects, the second DC voltage (b) may set the pair of neutralization transistors 1240 at the transistor-off state, e.g., as described below.

In some demonstrative aspects, as shown in FIG. 12, the first DC voltage (a) may include the Ground Voltage.

In some demonstrative aspects, as shown in FIG. 12, the second DC voltage (b) may be based on the voltage supply level VDD. In one example, as shown in FIG. 12, the second DC voltage (b) may be equal to the voltage supply level VDD.

In some demonstrative aspects, the pair of neutralization transistors 1240 may be implemented using PMOS transistors, for example, to provide a technical solution to support a lower bias voltage of the gates of the pair of neutralization transistors 1240, for example, compared to the bias voltage of the pair of neutralization transistors 1140 (FIG. 11).

In one example, as shown in FIG. 12, neutralization of the differential pair of amplification transistors 1220, e.g., at an amplification core-mode of AMP-OSC core 1210, may be implemented, for example, by a drain-source parasitic capacitance of a closed PMOS transistor. For example, the pair of neutralization transistors 1240 may be configure as a closed neutralization transistor, which may be connected, for example, in parallel to a gate-source parasitic capacitance of the differential pair of amplification transistors 1220, and in series to a gate-drain parasitic capacitance of the differential pair of amplification transistors 1220. For example, this configuration may be implemented assuming a relatively high resistance of a gate resistor connected to the gates of the pair of neutralization transistors 1240.

In some demonstrative aspects, both the pair of amplification transistors 1220 and the pair of neutralization transistors 1230 may be implemented using PMOS transistors. For example, according to these aspects, an additional power source, e.g., a negative voltage power source, may be used.

In other aspects, an AMP-OSC, e.g., AMP-OSC 1102 (FIG. 11) and/or AMP-OSC 1202, may include voltage input circuitry, e.g., voltage input circuitry 1236 (FIG. 12) and/or the voltage input circuitry 1136 (FIG. 11), which may be controllable to connect or disconnect a bias voltage (Vgs) to gates of the differential pair of amplification transistors of the AMP-OSC, e.g., as described above.

In other aspects, an AMP-OSC, e.g., AMP-OSC 1102 (FIG. 11) and/or AMP-OSC 1202, may include input-connection circuitry, for example, instead of voltage input circuitry, e.g., voltage input circuitry 1236 (FIG. 12) and/or the voltage input circuitry 1136 (FIG. 11).

In some demonstrative aspects, the input-connection circuitry may be configured to connect an AMP-OSC core of the AMP-OSC to an input terminal of the AMP-OSC, or to disconnect the AMP-OSC core from the input terminal of the AMP-OSC, e.g., as described below.

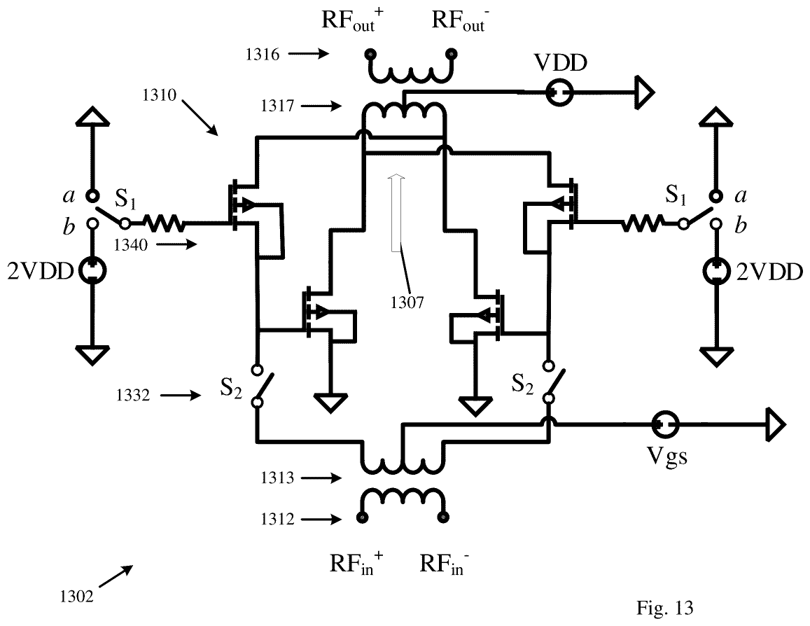

Reference is made to FIG. 13, which schematically illustrates an AMP-OSC 1302, in accordance with some demonstrative aspects. For example, AMP-OSC 1002 (FIG. 10) may include one or more elements of AMP-OSC 1302, and/or may perform one or more operations and/or functionalities of AMP-OSC 1302.

In some demonstrative aspects, as shown in FIG. 13, AMP-OSC 1302 may include an input terminal 1312, and an output terminal 1316.

In some demonstrative aspects, as shown in FIG. 13, AMP-OSC 1302 may include an AMP-OSC core 1310 connected between the input terminal 1312 and the output terminal 1316. For example, AMP-OSC core 1010 (FIG. 10) may include one or more elements of AMP-OSC core 1310, and/or may perform one or more operations and/or functionalities of AMP-OSC core 1310.

In some demonstrative aspects, as shown in FIG. 13, AMP-OSC 1302 may include input-connection circuitry 1332 connected between the input terminal 1312 and AMP-OSC core 1310.

In some demonstrative aspects, the input-connection circuitry 1332 may include a pair of input-switches, denoted S2, which may be connected between the input terminal 1312 and AMP-OSC core 1310.

In some demonstrative aspects, the input-connection circuitry 1332 may be controllable, e.g., by controller 1050 (FIG. 10), to connect AMP-OSC core 1310 to the input terminal 1312, for example, at an amplifying mode of the AMP-OSC 1302.

In some demonstrative aspects, the input-connection circuitry 1332 may be controllable to disconnect AMP-OSC core 1310 from the input terminal 1312, for example, at an oscillating mode of the AMP-OSC 1302.

In some demonstrative aspects, AMP-OSC 1302 may be configured to generate an oscillating signal 1307 at the oscillating mode of the AMP-OSC 1302.

In some demonstrative aspects, the input-connection circuitry 1332 may be controllable, e.g., by controller 1050 (FIG. 10), to selectively connect AMP-OSC core 1310 to the input terminal 1312 or to disconnect AMP-OSC core 1310 from the input terminal 1312, for example, at the oscillating mode of the AMP-OSC 1302, e.g., as described below.

In some demonstrative aspects, the input-connection circuitry 1332 may be controllable, e.g., by controller 1050 (FIG. 10), to connect AMP-OSC core 1310 to the input terminal 1312 or to disconnect AMP-OSC core 1310 from the input terminal 1312, for example, based on the oscillation-configuration setting in the second setting of the control signal 1009 (FIG. 10), which may be configured to set the oscillation-frequency of the oscillating signal 1307 at the oscillating mode of the AMP-OSC 1302.

In some demonstrative aspects, as shown in FIG. 13, input-connection circuitry 1332 may connect the AMP-OSC core 1310 to the input terminal 1312 via an input transformer 1313.

In one example, the input transformer 1313 may be disconnected from the AMP-OSC core 1310, for example, at the oscillating mode, for example, if such a disconnection is required, for example, considering a required frequency of oscillation, e.g., based on the oscillation-configuration setting in the second setting of the control signal 1009 (FIG. 10).

For example, the input transformer 1313 may be connected to the AMP-OSC core 1310 at the oscillating mode, e.g., in parallel to an output transformer 1317, e.g., as a result of the differential gate-drain short described above. For example, the input transformer 1313 may be connected to the AMP-OSC core 1310 at the oscillating mode, for example, to provide a technical solution to assist in lowering an oscillator tank inductance, for example, to achieve a higher oscillation frequency of the oscillating signal 1307.

In some demonstrative aspects, as shown in FIG. 13, AMP-OSC core 1310 may include a pair of neutralization transistors 1340 including a pair of NMOS transistors.

In other aspects, AMP-OSC core 1310 may be configured to utilize a pair of neutralization transistors 1340 including a pair of PMOS transistors, e.g., as described below.

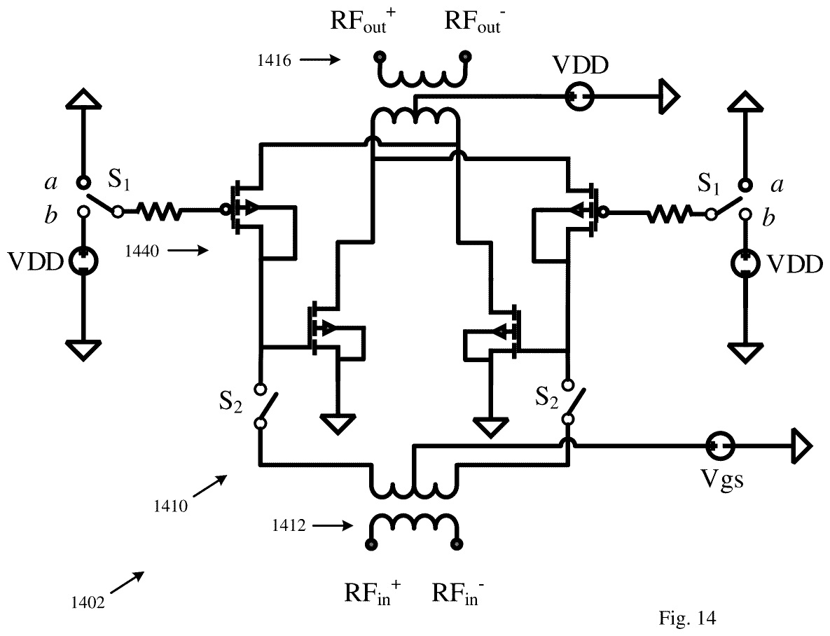

Reference is made to FIG. 14, which schematically illustrates an AMP-OSC 1402, in accordance with some demonstrative aspects. For example, AMP-OSC 1002 (FIG. 10) may include one or more elements of AMP-OSC 1402, and/or may perform one or more operations and/or functionalities of AMP-OSC 1402.

In some demonstrative aspects, as shown in FIG. 14, AMP-OSC 1402 may include an input terminal 1412, and an output terminal 1416.

In some demonstrative aspects, as shown in FIG. 14, AMP-OSC 1402 may include an AMP-OSC core 1410 connected between the input terminal 1412 and the output terminal 1416. For example, AMP-OSC core 1010 (FIG. 10) may include one or more elements of AMP-OSC core 1410, and/or may perform one or more operations and/or functionalities of AMP-OSC core 1410.

In some demonstrative aspects, as shown in FIG. 14, AMP-OSC core 1410 may include a pair of neutralization transistors 1440 including a pair of PMOS transistors 1440.

In one example, AMP-OSC 1402 may be configured similar to AMP-OSC 1302 (FIG. 13), for example, while including the pair of PMOS transistors 1440, e.g., instead of the pair of NMOS transistors 1340 (FIG. 13).

In some demonstrative aspects, an AMP-OSC, e.g., AMP-OSC 1102 (FIG. 11), AMP-OSC 1202 (FIG. 12), AMP-OSC 1302 (FIG. 13), and/or AMP-OSC 1402 (FIG. 14), may be configured according to a cross-coupled oscillator topology, in which an output (a drain) of a common-source amplifier may be connected into its input (a gate), e.g., with a phase offset of 0°.

In other aspects, for example, in case of a differential configuration, an AMP-OSC, e.g., AMP-OSC 1102 (FIG. 11), AMP-OSC 1202 (FIG. 12), AMP-OSC 1302 (FIG. 13), and/or AMP-OSC 1402 (FIG. 14), may be configured according to a cross-coupled oscillator topology, in which an output (a drain) of a first common-source amplifier may be connected into an input (a gate) of a second common-source amplifier, e.g., with a phase offset of 180°.

In some demonstrative aspects, the AMP-OSC may include a differential pair of amplification transistors, e.g., a neutralized pair of amplification transistors, which may utilize feedback capacitors, which may be connected between drains and gates of the differential pair of amplification transistors, for example, to compensate for losses caused by a parasitic gate-drain capacitance of the differential pair of amplification transistors, e.g., as described below. For example, the crossed feedback capacitance of the differential pair of amplification transistors may be utilized to mitigate, e.g., eliminate, an effect of the parasitic gate-drain capacitance, for example, to provide a technical solution to improve a stability of the AMP-OSC at the amplifying mode. For example, the crossed feedback capacitance of the differential pair of amplification transistors may be utilized to effectively decrease the feedback between the output and the input of the AMP-OSC.

In some demonstrative aspects, the feedback capacitors may be implemented by Metal-Oxide-Metal (MOM) capacitors, Metal-Insulator-Metal (MIM) capacitors, Metal-Oxide-Semiconductor (MOS) capacitors, or the like.

In some demonstrative aspects, the AMP-OSC may be configured to utilize a parasitic capacitance of a transistor as a feedback capacitor. For example, the parasitic capacitance of the transistor may have lower capacitance density, and better matching over corners to the parasitic gate-drain capacitance of the differential pair of amplification transistors.

In some demonstrative aspects, the transistor-based parasitic capacitors may be based on a gate-drain capacitance of a closed (not conducting) transistor, e.g., for better matching over corners.

In some demonstrative aspects, the transistor-based parasitic capacitors may be based on a drain-source capacitance and/or on both a gate-source capacitance and the gate-drain capacitance.

In some demonstrative aspects, the pair of neutralization transistors, e.g., implemented using the pair of transistor-based parasitic capacitors, may provide a technical solution to support easy switching of the AMP-OSC between the amplifying mode and the oscillating mode, for example, by changing the bias of the pair of neutralization transistors to turn them on. For example, this configuration may be implemented to achieve a very low impedance between the output and the input of the AMP-OSC, for example, to trigger oscillations of an AMP-OSC core of the AMP-OSC.

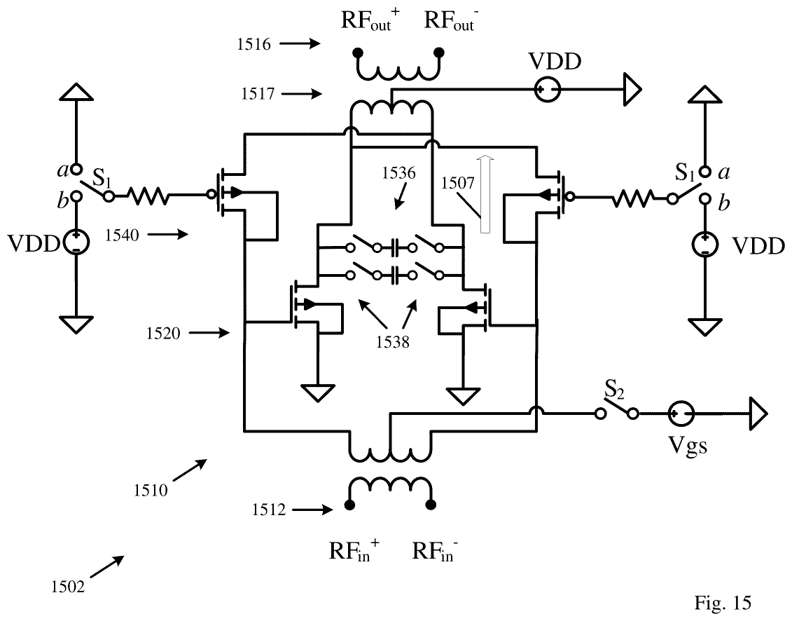

Reference is made to FIG. 15, which schematically illustrates an AMP-OSC 1502, in accordance with some demonstrative aspects. For example, AMP-OSC 1002 (FIG. 10) may include one or more elements of AMP-OSC 1502, and/or may perform one or more operations and/or functionalities of AMP-OSC 1502.

In some demonstrative aspects, as shown in FIG. 15, AMP-OSC 1502 may include an input terminal 1512, and an output terminal 1516.

In some demonstrative aspects, as shown in FIG. 15, AMP-OSC 1502 may include an AMP-OSC core 1510 connected between the input terminal 1512 and the output terminal 1516. For example, AMP-OSC core 1010 (FIG. 10) may include one or more elements of AMP-OSC core 1510, and/or may perform one or more operations and/or functionalities of AMP-OSC core 1510.

In some demonstrative aspects, as shown in FIG. 15, AMP-OSC core 1510 may include a differential pair of amplification transistors 1520.

In some demonstrative aspects, as shown in FIG. 15, AMP-OSC core 1510 may include a pair of neutralization transistors 1540.

In some demonstrative aspects, as shown in FIG. 15, AMP-OSC 1502 may include a capacitor bank 1536.

In some demonstrative aspects, as shown in FIG. 15, capacitor bank 1536 may be connected to drains of the differential pair of amplification transistors 1520.

In one example, the capacitor bank 1536 may be connected between the positive and negative drains of the differential pair of amplification transistors 1520, e.g., according to a cross couple pair oscillator topology.

In some demonstrative aspects, as shown in FIG. 15, the capacitor bank 1536 may include a plurality of capacitors 1538.

In some demonstrative aspects, AMP-OSC 1502 may be configured to generate an oscillating signal 1507 at an oscillating mode of the AMP-OSC 1502, e.g., as described below.

In some demonstrative aspects, the capacitor bank 1536 may be controllable, e.g., by controller 1050 (FIG. 10), to connect one or more capacitors 1538 of the capacitor bank 1536 to the AMP-OSC core 1510, for example, at the oscillating mode of AMP-OSC 1502.

In some demonstrative aspects, the capacitor bank 1536 may be disabled, for example, at the amplifying mode of AMP-OSC 1502.

In some demonstrative aspects, the capacitor bank 1536 may be controllable to connect one or more capacitors 1538 of the capacitor bank 1536 to AMP-OSC core 1510, for example, based on the oscillation-configuration setting to set the oscillation-frequency of the oscillating signal 1507 at the oscillating mode of AMP-OSC 1502.

In some demonstrative aspects, the capacitor bank 1536 may be configured to provide a technical solution to support matching the oscillation-frequency of the oscillating signal 1507 to a preferred oscillation frequency, e.g., according to the oscillation-configuration setting.

In some demonstrative aspects, the capacitor bank 1536 may be configured to provide a technical solution to support reducing the oscillation-frequency of the oscillating signal 1507, for example, to match a natural frequency, which may be achieved without implementation of the capacitor bank 1536.

In some demonstrative aspects, the capacitor bank 1536 may be controllable at the oscillating mode, e.g., based on the oscillation-configuration setting, to selectively connect the one or more capacitors 1538 of the capacitor bank 1536 to the AMP-OSC core 1510, for example, to provide a technical solution to reduce the oscillation frequency of the oscillating signal 1507, e.g., if necessary, for example, in case the preferred oscillation frequency of the oscillating signal 1507 is lower than the oscillation-frequency of the AMP-OSC core 1510.

In one example, an output transformer 1517 may be configured, e.g., optimized, for matching at the amplifying mode, e.g., which may not necessarily be optimized for the oscillating mode. This configuration with respect to the oscillating mode may result in an oscillation frequency, which may be different from the preferred oscillation frequency, e.g., according to the oscillation-configuration setting. For example, this configuration may have a missing degree of freedom, as the oscillation frequency may be set by output transformer 1517, which may be optimized for matching an output of the differential pair of amplification transistors 1520 at the amplification mode. For example, the output transformer 1517 may be optimized for matching the parasitic capacitance of the differential pair of amplification transistors 1520, e.g., implemented as a pair of common-source transistors.

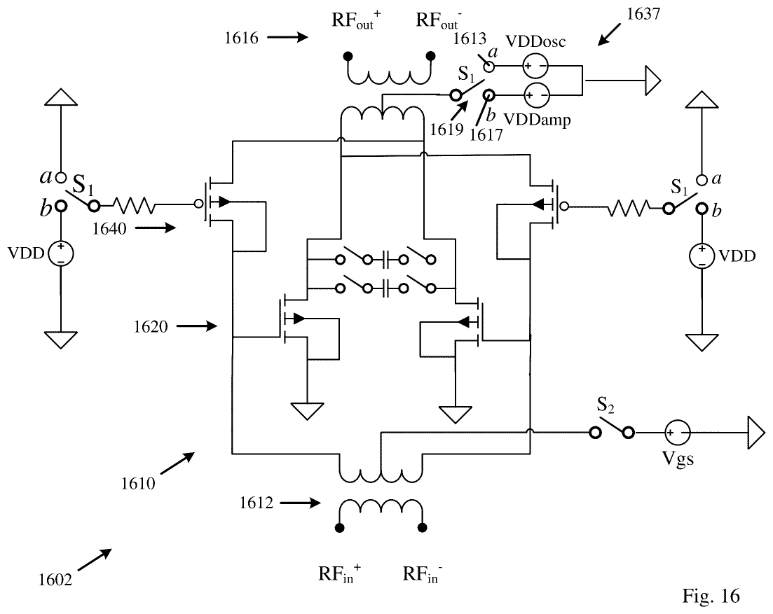

Reference is made to FIG. 16, which schematically illustrates an AMP-OSC 1602, in accordance with some demonstrative aspects. For example, AMP-OSC 1002 (FIG. 10) may include one or more elements of AMP-OSC 1602, and/or may perform one or more operations and/or functionalities of AMP-OSC 1602.

In some demonstrative aspects, as shown in FIG. 16, AMP-OSC 1602 may include an input terminal 1612, and an output terminal 1616.

In some demonstrative aspects, as shown in FIG. 16, AMP-OSC 1602 may include an AMP-OSC core 1610 connected between the input terminal 1612 and the output terminal 1616. For example, AMP-OSC core 1010 (FIG. 10) may include one or more elements of AMP-OSC core 1610, and/or may perform one or more operations and/or functionalities of AMP-OSC core 1610.

In some demonstrative aspects, as shown in FIG. 16, AMP-OSC core 1610 may include a differential pair of amplification transistors 1620.

In some demonstrative aspects, as shown in FIG. 16, AMP-OSC core 1610 may include a pair of neutralization transistors 1640.

In some demonstrative aspects, as shown in FIG. 16, AMP-OSC 1602 may include voltage supply circuitry 1637, which may be controllable to supply a first voltage 1613 to the AMP-OSC core 1610, for example, at an amplification core-mode of AMP-OSC core 1610.

In some demonstrative aspects, voltage supply circuitry 1637 may be controllable to supply a second voltage 1617 to the AMP-OSC core 1610, for example, at an oscillation core-mode of AMP-OSC core 1610.

In some demonstrative aspects, the first voltage 1613 may be different from the second voltage 1617.

In one example, the second voltage 1617 may be lower than the first voltage 1613, for example, to provide a technical solution to limit a current consumption of the differential pair of amplification transistors 1620, for example, at the oscillation core-mode of AMP-OSC core 1610.

In other aspects, any other suitable first voltage 1613 and/or second voltage 1617 may be used.

In some demonstrative aspects, as shown in FIG. 16, the voltage supply circuitry 1637 may include a voltage-supply switch 1619, which may be controllable to switch between the first voltage 1613 and the second voltage 1617.

In other aspects, the voltage supply circuitry 1637 may include a variable voltage supplier (not shown in FIG. 16), which may be configured to supply a voltage, e.g., the first voltage 1613 or the second voltage 1617, to the AMP-OSC core 1610, for example, based on a control input of the AMP-OSC 1602, e.g., the control input 1009 (FIG. 10).

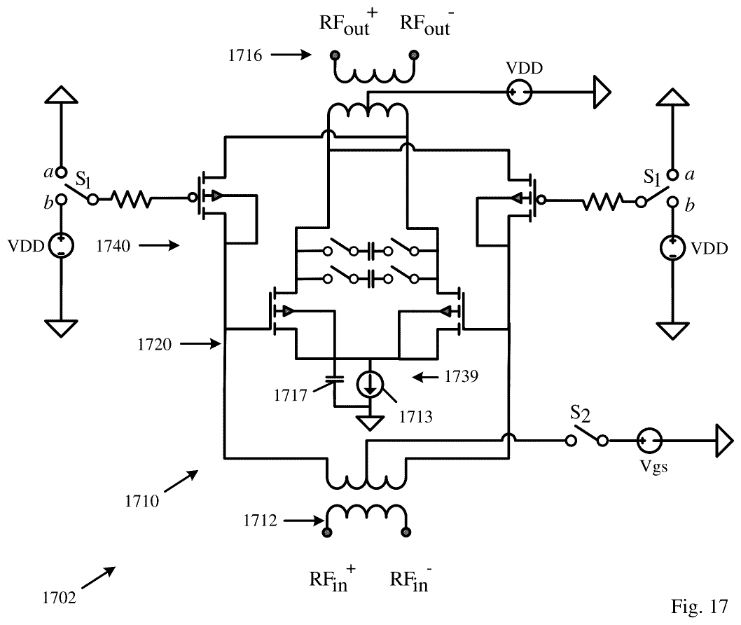

Reference is made to FIG. 17, which schematically illustrates an AMP-OSC 1702, in accordance with some demonstrative aspects. For example, AMP-OSC 1002 (FIG. 10) may include one or more elements of AMP-OSC 1702, and/or may perform one or more operations and/or functionalities of AMP-OSC 1702.

In some demonstrative aspects, as shown in FIG. 17, AMP-OSC 1702 may include an input terminal 1712, and an output terminal 1716.

In some demonstrative aspects, as shown in FIG. 17, AMP-OSC 1702 may include an AMP-OSC core 1710 connected between the input terminal 1712 and the output terminal 1717. For example, AMP-OSC core 1010 (FIG. 10) may include one or more elements of AMP-OSC core 1710, and/or may perform one or more operations and/or functionalities of AMP-OSC core 1710.

In some demonstrative aspects, as shown in FIG. 17, AMP-OSC core 1710 may include a differential pair of amplification transistors 1720.

In some demonstrative aspects, as shown in FIG. 17, AMP-OSC core 1710 may include a pair of neutralization transistors 1740.

In some demonstrative aspects, AMP-OSC 1702 may include current control circuitry 1739, which may be configured to set a first current for the AMP-OSC core 1710, for example, at an amplification core-mode of AMP-OSC core 1710.

In some demonstrative aspects, current control circuitry 1739 may be configured to set a second current for the AMP-OSC core 1710, for example, at an oscillation core-mode of AMP-OSC core 1710.

In some demonstrative aspects, the first current may be different from the second current.

In some demonstrative aspects, current control circuitry 1739 may include a variable current source 1713, which may be configured to generate the first current and the second current.

In some demonstrative aspects, variable current source 1713 may be controllable, e.g., according to control signal 1009 (FIG. 10), to set a current for the AMP-OSC core 1710, for example, based on a mode of operation of the AMP-OSC core 1710.

For example, variable current source 1713 may be controllable, e.g., according to control signal 1009 (FIG. 10), to set the current for the AMP-OSC core 1710, for example, at the oscillation core-mode, e.g., when gates of the differential pair of amplification transistors 1720 may be biased directly by a power supply.

In some demonstrative aspects, current control circuitry 1739 may include a capacitor 1717, which may be connected in parallel to the variable current source 1713.

In some demonstrative aspects, capacitor 1717 may be utilized to provide a technical solution to prevent substantial RF performance degradation, for example, due to the implementation of the current source 1713.

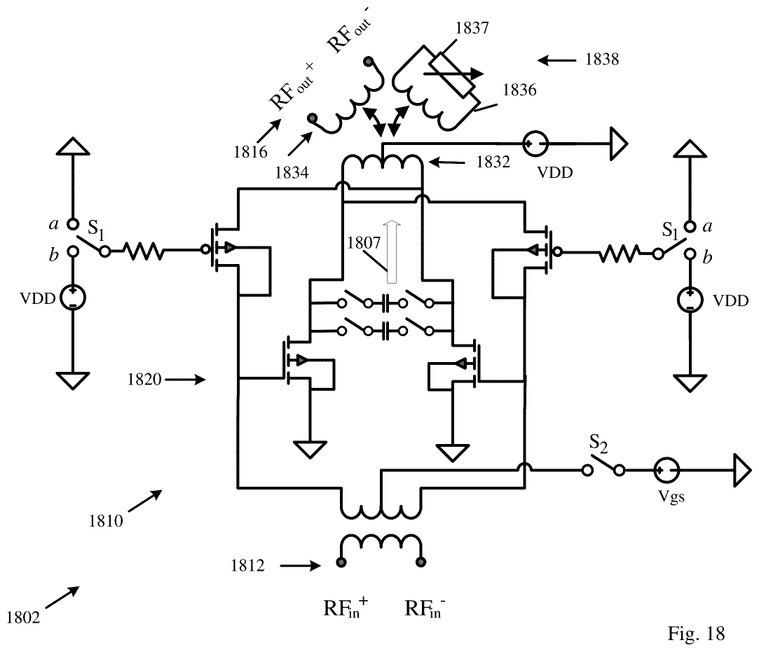

Reference is made to FIG. 18, which schematically illustrates an AMP-OSC 1802, in accordance with some demonstrative aspects. For example, AMP-OSC 1002 (FIG. 10) may include one or more elements of AMP-OSC 1802, and/or may perform one or more operations and/or functionalities of AMP-OSC 1802.

In some demonstrative aspects, as shown in FIG. 18, AMP-OSC 1802 may include an input terminal 1812, and an output terminal 1816.

In some demonstrative aspects, as shown in FIG. 18, AMP-OSC 1802 may include an AMP-OSC core 1810 connected between the input terminal 1812 and the output terminal 1816. For example, AMP-OSC core 1010 (FIG. 10) may include one or more elements of AMP-OSC core 1810, and/or may perform one or more operations and/or functionalities of AMP-OSC core 1810.

In some demonstrative aspects, as shown in FIG. 18, AMP-OSC core 1810 may include a differential pair of amplification transistors 1820.

In some demonstrative aspects, AMP-OSC 1802 may be configured to generate an oscillating signal 1807 at an oscillating mode of the AMP-OSC 1802, e.g., as described below.

In some demonstrative aspects, as shown in FIG. 18, AMP-OSC 1802 may include a variable-inductance transformer 1838 connected between AMP-OSC core 1810 and the output terminal 1816, e.g., as described below.

In some demonstrative aspects, as shown in FIG. 18, variable-inductance transformer 1838 may be connected to drains of the differential pair of amplification transistors 1820.

In some demonstrative aspects, as shown in FIG. 18, the variable-inductance transformer 1838 may include a three-way (3-way) transformer, e.g., as described below.

In some demonstrative aspects, as shown in FIG. 18, the variable-inductance transformer 1838 may include a first inductor 1832 connected to AMP-OSC core 1810, e.g., as described below.

In some demonstrative aspects, as shown in FIG. 18, the variable-inductance transformer 1838 may include a second inductor 1834 coupled to the first inductor 1832, for example, to provide the oscillating signal 1807 to the output terminal 1816, e.g., as described below.

In some demonstrative aspects, as shown in FIG. 18, the variable-inductance transformer 1838 may include a third inductor 1836 coupled to the first inductor 1832 and to the second inductor 1834, e.g., as described below.

In some demonstrative aspects, as shown in FIG. 18, the third inductor 1833 may be connected to a variable load 1837, e.g., as described below.

In some demonstrative aspects, an inductance of the variable-inductance transformer 1838 may be configurable, for example, based on the second setting of control signal 1009 (FIG. 10) at the oscillating mode, which may be configured to set the oscillation-frequency of the oscillating signal 1807 at the oscillating mode.

In some demonstrative aspects, the variable load 1837 may be configurable, for example, based on the oscillation-configuration setting to set the oscillation-frequency of the oscillating signal 1807 at the oscillating mode.

In some demonstrative aspects, the variable-inductance transformer 1838 may be configured to provide a technical solution to support matching between the oscillation-frequency of the oscillating signal 1807 and a preferred oscillation frequency of the oscillating signal 1807, for example, based on the oscillation-configuration setting of control signal 1009 (FIG. 10) at the oscillating mode.

In some demonstrative aspects, the variable load 1837 may be configured to tune an inductance of the variable-inductance transformer 1838, for example, by coupling the first inductor 1832 and the second inductor 1834 to the third inductor 1836 including the variable load 1837.

In some demonstrative aspects, a controller, e.g., controller 1050 (FIG. 10), may be configured to modify the variable load 1837, for example, between short and open, which may change an inductance of the third inductor 1836. This inductance change may possibly result in a slight degradation of the Quality (Q) factor of the third inductor 1836.

In some demonstrative aspects, the variable-inductance transformer 1838 may be configured to provide a technical solution to support relatively low inductance variations. For example, the variable-inductance transformer 1838 may support a variance of about 20 percent of the inductance of the third inductor 1836.

In some demonstrative aspects, the variable-inductance transformer 1838 may include a switchable winding (not shown in FIG. 18), e.g., as described below.

In some demonstrative aspects, the switchable winding may be configured to provide a technical solution to support relatively high inductance variations, e.g., as described below.

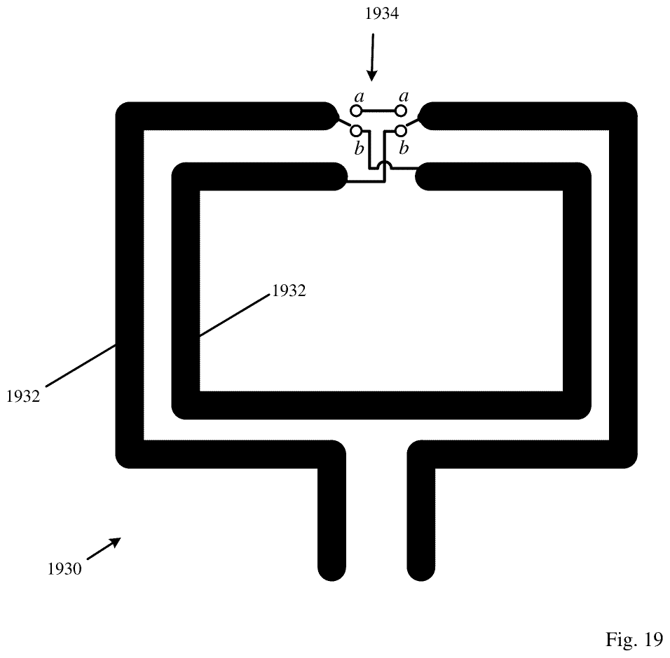

Reference is made to FIG. 19, which schematically illustrates a switchable winding 1930, in accordance with some demonstrative aspects.

In some demonstrative aspects, at least one of the first inductor 1832 (FIG. 18), the second inductor 1834 (FIG. 18), and/or the third inductor 1836 (FIG. 18) may include switchable winding 1930.

In some demonstrative aspects, an AMP-OSC, e.g., AMP-OSC 1102 (FIG. 11), AMP-OSC 1202 (FIG. 12), AMP-OSC 1302 (FIG. 13), AMP-OSC 1402 (FIG. 14), AMP-OSC 1502 (FIG. 15), AMP-OSC 1602 (FIG. 16), AMP-OSC 1702 (FIG. 17), and/or AMP-OSC 1802 (FIG. 18), may include an input transformer, e.g., input transformer 1113 (FIG. 11) and/or input transformer 1313 (FIG. 13), which may include the switchable winding 1930, e.g., on a primary side of the input transformer, and/or on a secondary side of the input transformer.

In some demonstrative aspects, an AMP-OSC, e.g., AMP-OSC 1102 (FIG. 11), AMP-OSC 1202 (FIG. 12), AMP-OSC 1302 (FIG. 13), AMP-OSC 1402 (FIG. 14), AMP-OSC 1502 (FIG. 15), AMP-OSC 1602 (FIG. 16), AMP-OSC 1702 (FIG. 17), and/or AMP-OSC 1802 (FIG. 18), may include an output transformer, e.g., output transformer 1317 (FIG. 13) and/or output transformer 1517 (FIG. 15), which may include the switchable winding 1930, e.g., on a primary side of the output transformer, and/or on a secondary side of the output transformer.

In some demonstrative aspects, as shown in FIG. 19, switchable winding 1930 may include a plurality of turns 1932.

In some demonstrative aspects, the switchable winding 1930 may be controllable, e.g., by controller 1050 (FIG. 10), to connect one or more turns 1932 of the plurality of turns 1932 between AMP-OSC core 1810 (FIG. 18) and the output terminal 1816 (FIG. 18), for example, based on the oscillation-configuration setting, which may be configured to set the oscillation-frequency of the oscillating signal 1807 (FIG. 18) at the oscillating mode of AMP-OSC 1802 (FIG. 18).

In some demonstrative aspects, as shown in FIG. 19, switchable winding 1930 may include a plurality of switches 1934, which may be controllable, e.g., by controller 1050 (FIG. 10), to select the number of the one or more turns 1932, which may be connected between AMP-OSC core 1810 (FIG. 18) and the output terminal 1816 (FIG. 18).

In some demonstrative aspects, the plurality of switches 1934 may be set to a state “a”, for example, to set switchable winding 1930 to include a single turn 1932.

In some demonstrative aspects, the plurality of switches 1934 may be set to a state “b”, to set switchable winding 1930 to include two turns 1932, for example, which may significantly increase the inductance of switchable winding 1930, for example, compared to the state “a”.

In some demonstrative aspects, the switchable winding 1930 may be configured to provide a technical solution to support relatively high inductance variations, for example, coarse variations, e.g., with a factor of 1.5 and above, of the oscillation-frequency of the oscillating signal 1807 (FIG. 18), for example, at the oscillating mode of AMP-OSC 1802 (FIG. 18).

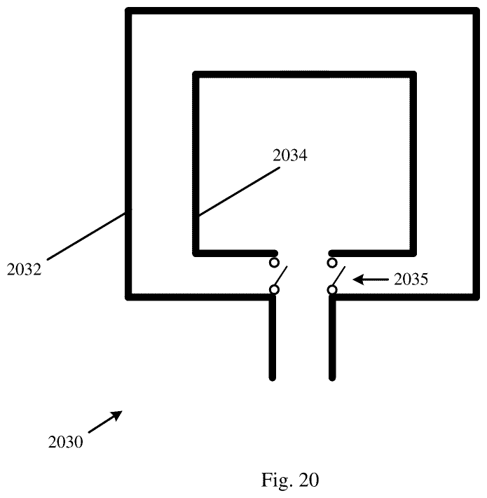

Reference is made to FIG. 20, which schematically illustrates a switchable winding 2030, in accordance with some demonstrative aspects.

In some demonstrative aspects, at least one of the first inductor 1832 (FIG. 18), the second inductor 1834 (FIG. 18), and/or the third inductor 1836 (FIG. 18) may include switchable winding 2030.

In some demonstrative aspects, an AMP-OSC, e.g., AMP-OSC 1102 (FIG. 11), AMP-OSC 1202 (FIG. 12), AMP-OSC 1302 (FIG. 13), AMP-OSC 1402 (FIG. 14), AMP-OSC 1502 (FIG. 15), AMP-OSC 1602 (FIG. 16), AMP-OSC 1702 (FIG. 17), and/or AMP-OSC 1802 (FIG. 18), may include an input transformer, e.g., input transformer 1113 (FIG. 11) and/or input transformer 1313 (FIG. 13), which may include the switchable winding 2030, e.g., on a primary side of the input transformer, and/or on a secondary side of the input transformer.

In some demonstrative aspects, an AMP-OSC, e.g., AMP-OSC 1102 (FIG. 11), AMP-OSC 1202 (FIG. 12), AMP-OSC 1302 (FIG. 13), AMP-OSC 1402 (FIG. 14), AMP-OSC 1502 (FIG. 15), AMP-OSC 1602 (FIG. 16), AMP-OSC 1702 (FIG. 17), and/or AMP-OSC 1802 (FIG. 18), may include an output transformer, e.g., output transformer 1317 (FIG. 13) and/or output transformer 1517 (FIG. 15), which may include the switchable winding 2030, e.g., on a primary side of the output transformer, and/or on a secondary side of the output transformer.

In some demonstrative aspects, as shown in FIG. 20, switchable winding 2030 may include a first turn 2032 and a second turn 2034.

In some demonstrative aspects, the first turn 2032 may be connected between an AMP-OSC core of the AMP-OSC, e.g., the AMP-OSC core 1810 (FIG. 18), and an output terminal of the AMP-OSC, e.g., the output terminal 1816 (FIG. 18).

In some demonstrative aspects, as shown in FIG. 20, switchable winding 2030 may include winding switching circuitry 2035, which may be controllable, e.g., by controller 1050 (FIG. 10), to connect the second turn 2034 in parallel to the first turn 2032, for example, at the oscillating mode of AMP-OSC 1802 (FIG. 18).

In some demonstrative aspects, as shown in FIG. 20, winding switching circuitry 2035 may be controllable, e.g., by controller 1050 (FIG. 10), to disconnect the second turn 2034 from the first turn 2032, for example, at the amplification core-mode of AMP-OSC 1802 (FIG. 18).

In some demonstrative aspects, winding switching circuitry 2035 may be controlled to disconnect the second turn 2034 from the first turn 2032 at the amplification core-mode of the AMP-OSC, for example, to provide a technical solution to support a suitable inductance for the amplification core-mode. In some demonstrative aspects, winding switching circuitry 2035 may be controlled to connect the second turn 2034 in parallel to the first turn 2032 at the oscillation core-mode of the AMP-OSC, for example, to provide a technical solution to support a reduced inductance for the oscillation core-mode, for example, as an inductor of the amplification core-mode, e.g., the first turn 2032, may be connected in parallel to a smaller inductor, e.g., the second turn 2034.

Referring back to FIG. 10, in some demonstrative aspects, the AMP-OSC core 1010 may include a pair of oscillation transistors 1042, which may be configured to generate the oscillating signal 1007, for example, at the oscillating core-mode of the AMP-OSC core 1010, e.g., as described below. For example, the pair of neutralization transistors 1040 may be omitted.

In some demonstrative aspects, the pair of oscillation transistors 1042 may be configured to provide the oscillating signal 1007 to the output terminal 1016 at the oscillation core-mode of the AMP-OSC core 1010, e.g., as described below.

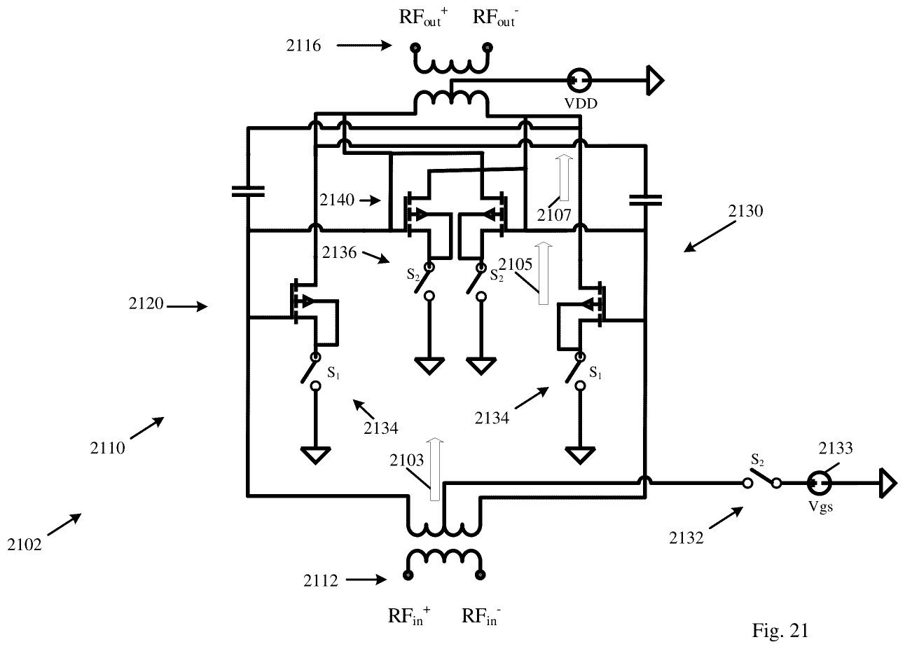

Reference is made to FIG. 21, which schematically illustrates an AMP-OSC 2102, in accordance with some demonstrative aspects. For example, AMP-OSC 1002 (FIG. 10) may include one or more elements of AMP-OSC 2102, and/or may perform one or more operations and/or functionalities of AMP-OSC 2102.

In some demonstrative aspects, as shown in FIG. 21, AMP-OSC 2102 may be switchable between an amplifying mode and an oscillating mode, for example, based on a control input, e.g., control input 1009 (FIG. 10).

In some demonstrative aspects, as shown in FIG. 21, AMP-OSC 2102 may include an input terminal 2112.

In some demonstrative aspects, as shown in FIG. 21, AMP-OSC 2102 may include an output terminal 2116.

In some demonstrative aspects, as shown in FIG. 21, AMP-OSC 2102 may include an AMP-OSC core 2110 connected between the input terminal 2112 and the output terminal 2116. For example, AMP-OSC core 1010 (FIG. 10) may include one or more elements of AMP-OSC core 2110, and/or may perform one or more operations and/or functionalities of AMP-OSC core 2110.

In some demonstrative aspects, the AMP-OSC core 2110 may be operable at an amplification core-mode corresponding to the amplifying mode.

In some demonstrative aspects, the AMP-OSC core 2110 may be operable at an oscillation core-mode corresponding to the oscillating mode.

In some demonstrative aspects, as shown in FIG. 21, AMP-OSC core 2110 may include a differential pair of amplification transistors 2120.

In some demonstrative aspects, as shown in FIG. 21, the differential pair of amplification transistors 2120 may be configured to amplify an input signal 2103, and to provide an amplified signal 2105 to the output terminal 2116, for example, at the amplifying core-mode.

In some demonstrative aspects, as shown in FIG. 21, AMP-OSC core 2110 may include a pair of oscillation transistors 2140, which may be configured to generate an oscillating signal 2107.

In some demonstrative aspects, as shown in FIG. 21, the pair of oscillation transistors 2140 may be configured to provide the oscillating signal 2107 to the output terminal 2116 at the oscillation core-mode.

In some demonstrative aspects, as shown in FIG. 21, the AMP-OSC 2102 may include switching circuitry 2130, which may be controllable, e.g., based on control input 1009 (FIG. 10), to connect the differential pair of amplification transistors 2120 to the output terminal 2116, and to disconnect the pair of oscillation transistors 2140 from the output terminal 2116, for example, at the amplification core-mode.

In some demonstrative aspects, switching circuitry 2130 may be controllable, e.g., based on control input 1009 (FIG. 10), to disconnect the differential pair of amplification transistors 2120 from the output terminal 2116, and to connect the pair of oscillation transistors 2140 to the output terminal 2116, for example, at the oscillation core-mode.

In some demonstrative aspects, as shown in FIG. 21, switching circuitry 2130 may include voltage input circuitry 2132, which may be controllable, e.g., based on control input 1009 (FIG. 10), to connect a bias voltage 2133 to gates of the differential pair of amplification transistors 2120, for example, at the amplification core-mode.

In some demonstrative aspects, voltage input circuitry 2132 may be controllable, e.g., based on control input 1009 (FIG. 10), to disconnect the bias voltage 2133 from the gates of the differential pair of amplification transistors 2120, for example, at the oscillation core-mode.

In some demonstrative aspects, as shown in FIG. 21, voltage input circuitry 2132 may include a switch, denoted S2, which may be controllable, e.g., based on control input 1009 (FIG. 10), to disconnect the bias voltage 2133 from the gates of the differential pair of amplification transistors 2120, for example, at the oscillation core-mode.

In some demonstrative aspects, as shown in FIG. 21, switching circuitry 2130 may include first switching circuitry 2134 connected to sources of the differential pair of amplification transistors 2120.

In some demonstrative aspects, as shown in FIG. 21, first switching circuitry 2134 may be controllable, e.g., based on control input 1009 (FIG. 10), to set the differential pair of amplification transistors 2120 at a transistor-amplification mode, for example, at the amplification core-mode of AMP-OSC core 2110.

In some demonstrative aspects, as shown in FIG. 21, first switching circuitry 2134 may be controllable, e.g., based on control input 1009 (FIG. 10), to set the differential pair of amplification transistors 2120 at a transistor-off mode, for example, at the oscillation core-mode of AMP-OSC core 2110.

In some demonstrative aspects, as shown in FIG. 21, first switching circuitry 2134 may include a pair of switches, denoted S1, which may be controllable, e.g., based on control input 1009 (FIG. 10), to connect the sources of the pair of amplification transistors 2120 to the Ground voltage.

In other aspects, first switching circuitry 2134 may include a single switch, which may be configured to connect a common source node, which may be connected between sources of the pair of amplification transistors 2120, to the Ground voltage.

In some demonstrative aspects, as shown in FIG. 21, switching circuitry 2130 may include second switching circuitry 2136 connected to sources of the pair of oscillation transistors 2140.

In some demonstrative aspects, as shown in FIG. 21, second switching circuitry 2136 may be controllable, e.g., based on control input 1009 (FIG. 10), to connect the sources of the pair of oscillation transistors 2140 to a Ground voltage, for example, at the oscillation core-mode of AMP-OSC core 2110.

In some demonstrative aspects, as shown in FIG. 21, second switching circuitry 2136 may be controllable, e.g., based on control input 1009 (FIG. 10), to disconnect the sources of the pair of oscillation transistors 2140 from the Ground voltage, for example, at the amplification core-mode of AMP-OSC core 2110.

In some demonstrative aspects, as shown in FIG. 21, second switching circuitry 2136 may include a pair of switches, denoted S2, which may be controllable, e.g., based on control input 1009 (FIG. 10), to connect the sources of the pair of oscillation transistors 2140 to the Ground voltage.

In other aspects, second switching circuitry 2136 may include a single switch, which may be configured to connect a common source node, which may be connected to sources of the pair of oscillation transistors 2140, to the Ground voltage.

In some demonstrative aspects, AMP-OSC 2102 may be implemented to provide a technical solution for a device, which may be operable as an amplifier or as an oscillator while using an area, which may be for example, similar to an area of AMP-OSC 1102 (FIG. 11), AMP-OSC 1202 (FIG. 12), AMP-OSC 1302 (FIG. 13), and/or AMP-OSC 1402 (FIG. 14).

In some demonstrative aspects, as shown in FIG. 21, AMP-OSC core 2110 may include an amplifier core, e.g., implemented as a cross-couple pair core including the differential pair of amplification transistors 2120.

In some demonstrative aspects, as shown in FIG. 21, AMP-OSC core 2110 may include an oscillator core, e.g., implemented as a common source core including the pair of oscillation transistors 2140.

In some demonstrative aspects, as shown in FIG. 21, the oscillator core may be connected in parallel to the amplifier core.

In some demonstrative aspects, as shown in FIG. 21, switching circuitry 2130 may include a plurality of switches, which may be controllable, e.g., based on control input 1009 (FIG. 10), to set an operating core, e.g., the amplifier core or the oscillator core, for example, according to an operating mode of AMP-OSC 2102.

For example, the amplifier core may operate at the amplification core-mode, and/or the oscillator core may operate at the oscillation core-mode.

In some demonstrative aspects, as shown in FIG. 21, AMP-OSC may be operable at the amplifying mode, for example, by setting switches S1 to an “on” state, and setting switches S2 to an “off” state.

In some demonstrative aspects, as shown in FIG. 21, AMP-OSC may be operable at the oscillating mode, for example, by setting switches S1 to the “off” state, and setting the switches S2 to the “on” state.

In some demonstrative aspects, one or more techniques and/or mechanisms, e.g., as described above, may be implemented to set the oscillation frequency of the oscillating signal 2107.

In some demonstrative aspects, AMP-OSC 2102 may include a capacitor bank (not shown in FIG. 21), e.g., capacitor bank 1536 (FIG. 15), which may be connected to drains of the pair of oscillation transistors 2140.

In some demonstrative aspects, the capacitor bank may be controllable, e.g., by controller 1050 (FIG. 1), to set the oscillation-frequency of the oscillating signal 2107 at the oscillating mode.

In some demonstrative aspects, AMP-OSC 2102 may include a variable-inductance transformer (not shown in FIG. 21), e.g., variable-inductance transformer 1838 (FIG. 18), which may be connected between the pair of oscillation transistors 2140 and the output terminal 2116, and/or between the pair of oscillation transistors 2140 and an input transformer at input terminal 2112.

In some demonstrative aspects, the variable-inductance transformer may be controllable, e.g., by controller 1050 (FIG. 1), to set the oscillation-frequency of the oscillating signal 2107 at the oscillating mode.

In some demonstrative aspects, AMP-OSC 2102 may include input-connection circuitry (not shown in FIG. 21), e.g., input-connection circuitry 1332 (FIG. 13), which may be connected between the input terminal 2112 and the pair of oscillation transistors 2140.

In some demonstrative aspects, the input-connection circuitry may be controllable, e.g., by controller 1050 (FIG. 1), to set the oscillation-frequency of the oscillating signal 2107 at the oscillating mode.

In some demonstrative aspects, AMP-OSC 2102 may be configured to provide a technical solution to support a compact size implementation, for example, as a size of circuitry of the pair of oscillation transistors 2140, e.g., a size of the oscillator core, may be set separately from and/or independently from the amplifier core. For example, a parasitic capacitance of the differential pair of amplification transistors 2120, e.g., the cross-coupled pair, may be reduced, for example, to support a simpler tuning of the oscillation frequency of the oscillating signal 2107.

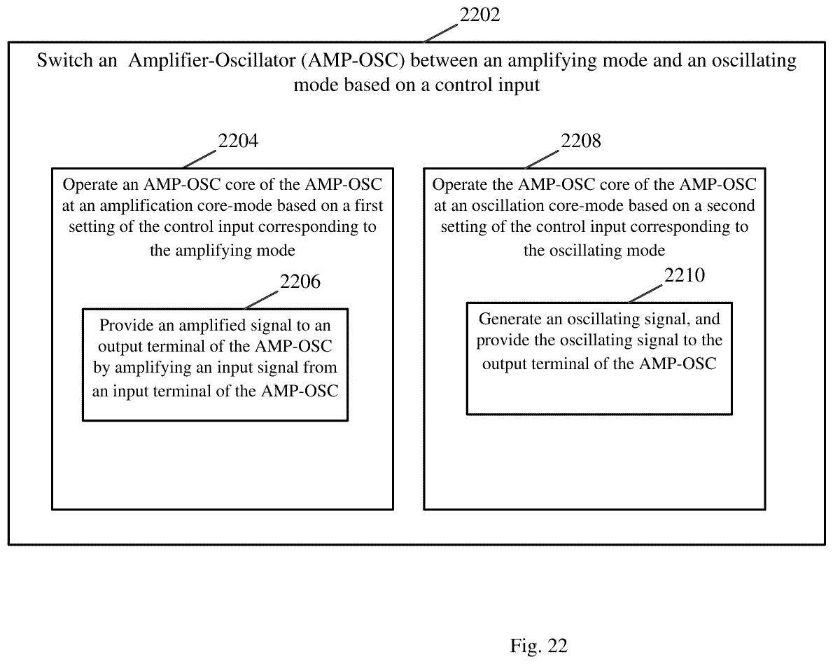

Reference is made to FIG. 22, which schematically illustrates a method of an AMP-OSC, in accordance with some demonstrative aspects. For example, one or more of the operations of the method of FIG. 22 may be performed by a radar system, e.g., radar system 900 (FIG. 9); a radar device, e.g., radar device 800 (FIG. 8); a radar front-end, e.g., radar front-end 804 (FIG. 8); a controller, e.g., controller 1050 (FIG. 10); and/or an AMP-OSC, e.g., AMP-OSC 1002 (FIG. 10), AMP-OSC 1102 (FIG. 11), AMP-OSC 1202 (FIG. 12), AMP-OSC 1302 (FIG. 13), AMP-OSC 1402 (FIG. 14), AMP-OSC 1502 (FIG. 15), AMP-OSC 1602 (FIG. 16), AMP-OSC 1702 (FIG. 17), AMP-OSC 1802 (FIG. 18), and/or AMP-OSC 2102 (FIG. 21).

As indicated at block 2202, the method may include switching an AMP-OSC between an amplifying mode and an oscillating mode based on a control input. For example, controller 1050 (FIG. 10) may be configured to control switching of the AMP-OSC 1002 (FIG. 10) between the amplifying mode and the oscillating mode, for example, according to the control input 1009 (FIG. 10), e.g., as described above.

As indicated at block 2204, switching the AMP-OSC between the amplifying mode and the oscillating mode may include operating an AMP-OSC core of the AMP-OSC at an amplification core-mode, for example, based on a first setting of the control input corresponding to the amplifying mode. For example, controller 1050 (FIG. 10) may be configured to operate the AMP-OSC core 1010 (FIG. 10) of the AMP-OSC 1002 (FIG. 10) at the amplification core-mode, for example, according to the first setting of the control input 1009 (FIG. 10), which may correspond to the amplifying mode, e.g., as described above.

As indicated at block 2206, operating the AMP-OSC core at the amplification core-mode may include providing an amplified signal to an output terminal of the AMP-OSC, for example, by amplifying an input signal from an input terminal of the AMP-OSC. For example, AMP-OSC core 1010 (FIG. 10) may be configured to provide the amplified signal 1005 (FIG. 10) to the output terminal 1016 (FIG. 10), for example, by amplifying the input signal 1003 (FIG. 10) from the input terminal 1012 (FIG. 10), e.g., as described above.

As indicated at block 2208, switching the AMP-OSC between the amplifying mode and the oscillating mode may include operating the AMP-OSC core of the AMP-OSC at an oscillation core-mode, for example, based on a second setting of the control input corresponding to the oscillating mode. For example, controller 1050 (FIG. 10) may be configured to operate the AMP-OSC core 1010 (FIG. 10) at the oscillation core-mode, for example, according to the second setting of the control input 1009 (FIG. 10), which may correspond to the oscillating mode, e.g., as described above.

As indicated at block 2210, operating the AMP-OSC core at the oscillation core-mode may include generating an oscillating signal and providing the oscillating signal to the output terminal. For example, AMP-OSC core 1010 (FIG. 10) may be configured to generate the oscillating signal 1007 (FIG. 10), and to provide the oscillating signal 1007 (FIG. 10) to the output terminal 1016 (FIG. 10), e.g., as described above.

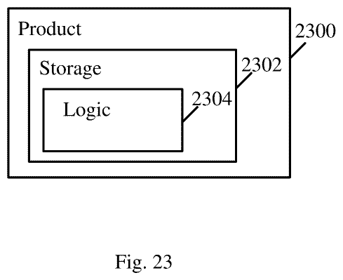

Reference is made to FIG. 23, which schematically illustrates a product of manufacture 2300, in accordance with some demonstrative aspects. Product 2300 may include one or more tangible computer-readable (“machine-readable”) non-transitory storage media 2302, which may include computer-executable instructions, e.g., implemented by logic 2304, operable to, when executed by at least one computer processor, enable the at least one computer processor to implement one or more operations and/or functionalities described with reference to any of the FIGS. 1-22, and/or one or more operations described herein. The phrases “non-transitory machine-readable medium” and “computer-readable non-transitory storage media” may be directed to include all machine and/or computer readable media, with the sole exception being a transitory propagating signal.

In some demonstrative aspects, product 2300 and/or machine-readable storage media 2302 may include one or more types of computer-readable storage media capable of storing data, including volatile memory, non-volatile memory, removable or non-removable memory, erasable or non-erasable memory, writeable or re-writeable memory, and the like. For example, machine-readable storage media 2302 may include, RAM, DRAM, Double-Data-Rate DRAM (DDR-DRAM), SDRAM, static RAM (SRAM), ROM, programmable ROM (PROM), erasable programmable ROM (EPROM), electrically erasable programmable ROM (EEPROM), flash memory (e.g., NOR or NAND flash memory), content addressable memory (CAM), polymer memory, phase-change memory, ferroelectric memory, silicon-oxide-nitride-oxide-silicon (SONOS) memory, a disk, a hard drive, and the like. The computer-readable storage media may include any suitable media involved with downloading or transferring a computer program from a remote computer to a requesting computer carried by data signals embodied in a carrier wave or other propagation medium through a communication link, e.g., a modem, radio or network connection.

In some demonstrative aspects, logic 2304 may include instructions, data, and/or code, which, if executed by a machine, may cause the machine to perform a method, process and/or operations as described herein. The machine may include, for example, any suitable processing platform, computing platform, computing device, processing device, computing system, processing system, computer, processor, or the like, and may be implemented using any suitable combination of hardware, software, firmware, and the like.

In some demonstrative aspects, logic 2304 may include, or may be implemented as, software, a software module, an application, a program, a subroutine, instructions, an instruction set, computing code, words, values, symbols, and the like. The instructions may include any suitable type of code, such as source code, compiled code, interpreted code, executable code, static code, dynamic code, and the like. The instructions may be implemented according to a predefined computer language, manner or syntax, for instructing a processor to perform a certain function. The instructions may be implemented using any suitable high-level, low-level, object-oriented, visual, compiled and/or interpreted programming language, machine code, and the like.

### EXAMPLES

The following examples pertain to further aspects.

Example 1 includes an apparatus comprising an Amplifier-Oscillator (AMP-OSC) switchable between an amplifying mode and an oscillating mode based on a control input, the AMP-OSC comprising an input terminal; an output terminal; and an AMP-OSC core connected between the input terminal and the output terminal, wherein the AMP-OSC core is operable at an amplification core-mode based on a first setting of the control input corresponding to the amplifying mode, and operable at an oscillation core-mode based on a second setting of the control input corresponding to the oscillating mode, wherein at the amplification core-mode the AMP-OSC core is to provide an amplified signal to the output terminal by amplifying an input signal from the input terminal, wherein at the oscillation core-mode the AMP-OSC core is to generate an oscillating signal and to provide the oscillating signal to the output terminal.

Example 2 includes the subject matter of Example 1, and optionally, wherein the AMP-OSC core comprises a differential pair of amplification transistors, wherein the differential pair of amplification transistors is configured to provide the amplified signal to the output terminal by amplifying the input signal from the input terminal at the amplification core-mode.

Example 3 includes the subject matter of Example 2, and optionally, wherein drains of the differential pair of amplification transistors are connected to the output terminal.

Example 4 includes the subject matter of Example 2 or 3, and optionally, wherein the differential pair of amplification transistors are disconnected from the input terminal at the oscillation core-mode.

Example 5 includes the subject matter of Example 4, and optionally, wherein gates of the differential pair of amplification transistors are connected to the input terminal at the amplification core-mode, wherein the gates of the differential pair of amplification transistors are disconnected from the input terminal at the oscillation core-mode.

Example 6 includes the subject matter of any one of Examples 1-5, and optionally, comprising voltage input circuitry controllable to connect a bias voltage to the AMP-OSC core at the amplification core-mode, and to disconnect the bias voltage from the AMP-OSC core at the oscillation core-mode.

Example 7 includes the subject matter of any one of Examples 1-6, and optionally, wherein the AMP-OSC is configured to set an oscillation-frequency of the oscillating signal at the oscillating mode based on the second setting of the control input.

Example 8 includes the subject matter of Example 7, and optionally, wherein the AMP-OSC is configured to set the oscillation-frequency of the oscillating signal at the oscillating mode based on an oscillation-configuration setting in the second setting of the control input.

Example 9 includes the subject matter of Example 8, and optionally, wherein the AMP-OSC comprises a capacitor bank comprising a plurality of capacitors, wherein the capacitor bank is controllable to connect one or more capacitors of the capacitor bank to the AMP-OSC core based on the oscillation-configuration setting to set the oscillation-frequency of the oscillating signal at the oscillating mode.

Example 10 includes the subject matter of Example 8 or 9, and optionally, comprising a variable-inductance transformer connected between the AMP-OSC core and the output terminal, wherein an inductance of the variable-inductance transformer is configurable based on the oscillation-configuration setting to set the oscillation-frequency of the oscillating signal at the oscillating mode.

Example 11 includes the subject matter of any one of Examples 8-10, and optionally, comprising input-connection circuitry connected between the input terminal and the AMP-OSC core, wherein the input-connection circuitry is controllable to connect the AMP-OSC core to the input terminal or to disconnect the AMP-OSC core from the input terminal based on the oscillation-configuration setting to set the oscillation-frequency of the oscillating signal at the oscillating mode.

Example 12 includes the subject matter of any one of Examples 8-11, and optionally, wherein the AMP-OSC is configured to set a first oscillation-frequency of the oscillating signal based on a first oscillation-configuration setting in the second setting of the control input, wherein the AMP-OSC is configured to set a second oscillation-frequency of the oscillating signal based on a second oscillation-configuration setting in the second setting of the control input, wherein the first oscillation-configuration setting is different from the second oscillation-configuration setting, wherein the first oscillation frequency is different from the second oscillation frequency.

Example 13 includes the subject matter of any one of Examples 1-12, and optionally, comprising voltage supply circuitry controllable to supply a first voltage to the AMP-OSC core at the amplification core-mode, and to supply a second voltage to the AMP-OSC core at the oscillation core-mode, wherein the first voltage is different from the second voltage.

Example 14 includes the subject matter of Example 13, and optionally, wherein the voltage supply circuitry comprises a voltage-supply switch controllable to switch between the first voltage and the second voltage.

Example 15 includes the subject matter of Example 13 or 14, and optionally, wherein the voltage supply circuitry comprises a variable voltage supply configured to supply the first voltage or the second voltage to the AMP-OSC core based on the control input.

Example 16 includes the subject matter of any one of Examples 1-15, and optionally, comprising current control circuitry configured to set a first current for the AMP-OSC core at the amplification core-mode, and to set a second current for the AMP-OSC core at the oscillation core-mode, wherein the first current is different from the second current.

Example 17 includes the subject matter of Example 16, and optionally, wherein the current control circuitry comprises a variable current source configured to set the first current and the second current, and a capacitor connected in parallel to the current source.

Example 18 includes the subject matter of any one of Examples 1-17, and optionally, comprising a variable-inductance transformer connected between the AMP-OSC core and the output terminal, wherein an inductance of the variable-inductance transformer is configurable based on the second setting of the control signal at the oscillating mode.

Example 19 includes the subject matter of Example 18, and optionally, wherein the inductance of the variable-inductance transformer is configurable, based on an oscillation-configuration setting in the second setting of the control input, to set an oscillation-frequency of the oscillating signal at the oscillating mode.

Example 20 includes the subject matter of Example 19, and optionally, wherein the variable-inductance transformer comprises a three-way (3-way) transformer comprising a first inductor connected to the AMP-OSC core, a second inductor coupled to the first inductor to provide the oscillating signal to the output terminal, and a third inductor coupled to the first inductor and to the second inductor, wherein the third inductor is connected to a variable load, which is configurable based on the oscillation-configuration setting.

Example 21 includes the subject matter of Example 19 or 20, and optionally, wherein the variable-inductance transformer comprises a switchable winding comprising a plurality of turns, wherein the switchable winding is controllable to connect one or more turns of the plurality of turns between the AMP-OSC core and the output terminal based on the oscillation-configuration setting.

Example 22 includes the subject matter of Example 21, and optionally, wherein the plurality of turns comprises a first turn and a second turn, the first turn connected between the AMP-OSC core and the output terminal, wherein the switchable winding comprises winding switching circuitry controllable to connect the second turn in parallel to the first turn at the oscillation core mode, and to disconnect the second turn from the first turn at the amplification core-mode.

Example 23 includes the subject matter of any one of Examples 19-22, and optionally, wherein the AMP-OSC is configured to set a first inductance of the variable-inductance transformer based on a first oscillation-configuration setting in the second setting of the control input, wherein the AMP-OSC is configured to set a second inductance of the variable-inductance transformer based on a second oscillation-configuration setting in the second setting of the control input, wherein the first oscillation-configuration setting is different from the second oscillation-configuration setting, wherein the first inductance is different from the second inductance.

Example 24 includes the subject matter of any one of Examples 1-23, and optionally, comprising input-connection circuitry configured to connect the AMP-OSC core to the input terminal to amplify the input signal from the input terminal based on the first setting of the control input, and to disconnect the AMP-OSC core from the input terminal based on the second setting of the control input.

Example 25 includes the subject matter of Example 24, and optionally, wherein the input-connection circuitry comprises a pair of input-switches connected between the input terminal and the AMP-OSC core.

Example 26 includes the subject matter of any one of Examples 1-25, and optionally, wherein the AMP-OSC core comprises a differential pair of amplification transistors; and a pair of neutralization transistors configured to neutralize a parasitic capacitance of the differential pair of amplification transistors at the amplification core-mode, and to cross-couple connect the differential pair of amplification transistors at the oscillation core-mode.

Example 27 includes the subject matter of Example 26, and optionally, wherein the pair of neutralization transistors are controllable to be at a transistor-off state to neutralize the parasitic capacitance of the differential pair of amplification transistors at the amplification core-mode, wherein the pair of neutralization transistors are controllable to be at a transistor-on state to cross-couple connect the differential pair of amplification transistors at the oscillation core-mode.

Example 28 includes the subject matter of Example 27, and optionally, comprising a pair of gate switches controllable to switch a bias voltage of gates of the pair of neutralization transistors between a first Direct Current (DC) voltage and a second DC voltage, wherein the first DC voltage is to set the pair of neutralization transistors at the transistor-on state, wherein the second DC voltage is to set the pair of neutralization transistors at the transistor-off state.

Example 29 includes the subject matter of Example 28, and optionally, wherein the pair of neutralization transistors comprises a pair of N-channel Metal Oxide Semiconductor (NMOS) transistors, wherein the first DC voltage comprises a Ground voltage, the second DC voltage is based on a voltage supply level VDD.

Example 30 includes the subject matter of Example 28, and optionally, wherein the pair of neutralization transistors comprises a pair of P-channel Metal Oxide Semiconductor (PMOS) transistors, wherein the first DC voltage comprises a voltage supply level (VDD), the second DC voltage comprising a Ground voltage.

Example 31 includes the subject matter of any one of Examples 26-30, and optionally, comprising voltage input circuitry controllable to connect a bias voltage to gates of the differential pair of amplification transistors at the amplification core-mode, and to disconnect the bias voltage from the gates of the differential pair of amplification transistors at the oscillation core-mode.

Example 32 includes the subject matter of any one of Examples 26-31, and optionally, wherein a drain of a first amplification transistor of the differential pair of amplification transistors is connected to a first differential output of the output terminal, wherein a drain of a second amplification transistor of the differential pair of amplification transistors is connected to a second differential output of the output terminal, wherein a first neutralization transistor of the pair of neutralization transistors is connected between a gate of the first amplification transistor and the drain of the second amplification transistor, wherein a second neutralization transistor of the pair of neutralization transistors is connected between a gate of the second amplification transistor and the drain of the first amplification transistor.

Example 33 includes the subject matter of Example 32, and optionally, wherein one of a source or a drain of the first neutralization transistor is connected to the gate of the first amplification transistor, and another one of the source or the drain of the first neutralization transistor is connected to the drain of the second amplification transistor, wherein one of a source or a drain of the second neutralization transistor is connected to the gate of the second amplification transistor, and another one of the source or the drain of the second neutralization transistor is connected to the drain of the first amplification transistor.

Example 34 includes the subject matter of any one of Examples 26-33, and optionally, wherein the differential pair of amplification transistors comprises a pair of P-channel Metal Oxide Semiconductor (PMOS) transistors or a pair of N-channel Metal Oxide Semiconductor (NMOS) transistors.

Example 35 includes the subject matter of any one of Examples 1-25, and optionally, wherein the AMP-OSC core comprises a differential pair of amplification transistors configured to amplify the input signal, and to provide the amplified signal to the output terminal at the amplification core-mode; and a pair of oscillation transistors configured to generate the oscillating signal, and to provide the oscillating signal to the output terminal at the oscillation core-mode.

Example 36 includes the subject matter of Example 35, and optionally, wherein the AMP-OSC comprises switching circuitry controllable to connect the differential pair of amplification transistors to the output terminal and to disconnect the pair of oscillation transistors from the output terminal at the amplification core-mode, and to disconnect the differential pair of amplification transistors from the output terminal and to connect the pair of oscillation transistors to the output terminal at the oscillation core-more.

Example 37 includes the subject matter of Example 36, and optionally, wherein the switching circuitry comprises voltage input circuitry controllable to connect a bias voltage to gates of the differential pair of amplification transistors at the amplification core-mode, and to disconnect the bias voltage from the gates of the differential pair of amplification transistors at the oscillation core-mode; first switching circuitry connected to sources of the differential pair of amplification transistors, wherein the first switching circuitry is controllable to set the differential pair of amplification transistors at a transistor-amplification mode at the amplification core-mode, and to set the differential pair of amplification transistors at a transistor-off mode at the oscillation core-mode; and second switching circuitry connected to sources of the pair of oscillation transistors, wherein the second switching circuitry is controllable to connect the sources of the pair of oscillation transistors to a Ground voltage at the oscillation core-mode, and to disconnect the sources of the pair of oscillation transistors from the Ground voltage at the amplification core-mode.

Example 38 includes the subject matter of any one of Examples 1-37, and optionally, comprising a Local Oscillator (LO) to generate an LO signal, wherein the input signal is based on the LO signal.

Example 39 includes the subject matter of any one of Examples 1-38, and optionally, comprising a controller configured to provide the control input to control setting of the AMP-OSC at the amplifying mode or at the oscillating mode.

Example 40 includes the subject matter of Example 39, and optionally, wherein the controller is configured to provide the second setting of the control input at a test mode to test a Radio Frequency (RF) chain comprising the AMP-OSC.

Example 41 includes the subject matter of any one of Examples 1-40, and optionally, comprising a Radio Frequency (RF) chain comprising the AMP-OSC.

Example 42 includes the subject matter of any one of Examples 1-41, and optionally, comprising a radar device, the radar device comprising a plurality of Transmit (Tx) antennas connected to a plurality of Tx chains, a plurality of Rx antennas connected to a plurality of Rx chains, and a radar processor to generate radar information based on radar Rx signals processed by the Rx chains, wherein a radar Rx chain or a radar Tx chain comprises the AMP-OSC.

Example 43 includes the subject matter of Example 42, and optionally, comprising a vehicle, the vehicle comprising the radar device, and a system controller to control one or more systems of the vehicle based on the radar information.

Example 44 includes an Amplifier-Oscillator (AMP-OSC) according to any of Examples 1-43.

Example 45 includes a Radio Frequency (RF) chain comprising an Amplifier-Oscillator (AMP-OSC) according to any of Examples 1-43.

Example 46 includes a radar device comprising an Amplifier-Oscillator (AMP-OSC) according to any of Examples 1-43.

Example 47 includes a vehicle comprising a radar system, the radar system comprising an Amplifier-Oscillator (AMP-OSC) according to any of Examples 1-43.

Example 48 includes Amplifier-Oscillator (AMP-OSC) means according to any of Examples 1-43.

Example 49 includes a method of an Amplifier-Oscillator (AMP-OSC) according to any of Examples 1-43.

Functions, operations, components and/or features described herein with reference to one or more aspects, may be combined with, or may be utilized in combination with, one or more other functions, operations, components and/or features described herein with reference to one or more other aspects, or vice versa.

While certain features have been illustrated and described herein, many modifications, substitutions, changes, and equivalents may occur to those skilled in the art. It is, therefore, to be understood that the appended claims are intended to cover all such modifications and changes as fall within the true spirit of the disclosure.

What is claimed is:

1. An apparatus comprising:
an Amplifier-Oscillator (AMP-OSC) switchable between an amplifying mode and an oscillating mode based on a control input, the AMP-OSC comprising:
an input terminal;
an output terminal; and
an AMP-OSC core connected between the input terminal and the output terminal, wherein the AMP-OSC core is operable at an amplification core-mode based on a first setting of the control input corresponding to the amplifying mode, and operable at an oscillation core-mode based on a second setting of the control input corresponding to the oscillating mode, wherein at the amplification core-mode the AMP-OSC core is to provide an amplified signal to the output terminal by amplifying an input signal from the input terminal, wherein at the oscillation core-mode the AMP-OSC core is to generate an oscillating signal and to provide the oscillating signal to the output terminal.

2. The apparatus of claim 1, wherein the AMP-OSC core comprises a differential pair of amplification transistors, wherein the differential pair of amplification transistors is configured to provide the amplified signal to the output terminal by amplifying the input signal from the input terminal at the amplification core-mode.

3. The apparatus of claim 2, wherein drains of the differential pair of amplification transistors are connected to the output terminal.

4. The apparatus of claim 1 comprising voltage input circuitry controllable to connect a bias voltage to the AMP-OSC core at the amplification core-mode, and to disconnect the bias voltage from the AMP-OSC core at the oscillation core-mode.

5. The apparatus of claim 1, wherein the AMP-OSC is configured to set an oscillation-frequency of the oscillating signal at the oscillating mode based on the second setting of the control input.

6. The apparatus of claim 5, wherein the AMP-OSC is configured to set the oscillation-frequency of the oscillating signal at the oscillating mode based on an oscillation-configuration setting in the second setting of the control input.

7. The apparatus of claim 6, wherein the AMP-OSC comprises a capacitor bank comprising a plurality of capacitors, wherein the capacitor bank is controllable to connect one or more capacitors of the capacitor bank to the AMP-OSC core based on the oscillation-configuration setting to set the oscillation-frequency of the oscillating signal at the oscillating mode.

8. The apparatus of claim 6 comprising a variable-inductance transformer connected between the AMP-OSC core and the output terminal, wherein an inductance of the variable-inductance transformer is configurable based on the oscillation-configuration setting to set the oscillation-frequency of the oscillating signal at the oscillating mode.

9. The apparatus of claim 6 comprising input-connection circuitry connected between the input terminal and the AMP-OSC core, wherein the input-connection circuitry is controllable to connect the AMP-OSC core to the input terminal or to disconnect the AMP-OSC core from the input terminal based on the oscillation-configuration setting to set the oscillation-frequency of the oscillating signal at the oscillating mode.

10. The apparatus of claim 1 comprising voltage supply circuitry controllable to supply a first voltage to the AMP-OSC core at the amplification core-mode, and to supply a second voltage to the AMP-OSC core at the oscillation core-mode, wherein the first voltage is different from the second voltage.

11. The apparatus of claim 1 comprising current control circuitry configured to set a first current for the AMP-OSC core at the amplification core-mode, and to set a second current for the AMP-OSC core at the oscillation core-mode, wherein the first current is different from the second current.

12. The apparatus of claim 1 comprising a variable-inductance transformer connected between the AMP-OSC core and the output terminal, wherein an inductance of the variable-inductance transformer is configurable based on the second setting of the control signal at the oscillating mode.

13. The apparatus of claim 12, wherein the inductance of the variable-inductance transformer is configurable, based on an oscillation-configuration setting in the second setting of the control input, to set an oscillation-frequency of the oscillating signal at the oscillating mode.

14. The apparatus of claim 13, wherein the variable-inductance transformer comprises a three-way (3-way) transformer comprising a first inductor connected to the AMP-OSC core, a second inductor coupled to the first inductor to provide the oscillating signal to the output terminal, and a third inductor coupled to the first inductor and to the second inductor, wherein the third inductor is connected to a variable load, which is configurable based on the oscillation-configuration setting.

15. The apparatus of claim 13, wherein the variable-inductance transformer comprises a switchable winding comprising a plurality of turns, wherein the switchable winding is controllable to connect one or more turns of the plurality of turns between the AMP-OSC core and the output terminal based on the oscillation-configuration setting.

16. The apparatus of claim 1 comprising input-connection circuitry configured to connect the AMP-OSC core to the input terminal to amplify the input signal from the input terminal based on the first setting of the control input, and to disconnect the AMP-OSC core from the input terminal based on the second setting of the control input.

17. The apparatus of claim 1, wherein the AMP-OSC core comprises:
a differential pair of amplification transistors; and
a pair of neutralization transistors configured to neutralize a parasitic capacitance of the differential pair of amplification transistors at the amplification core-mode, and to cross-couple connect the differential pair of amplification transistors at the oscillation core-mode.

18. The apparatus of claim 17, wherein the pair of neutralization transistors are controllable to be at a transistor-off state to neutralize the parasitic capacitance of the differential pair of amplification transistors at the amplification core-mode, wherein the pair of neutralization transistors are controllable to be at a transistor-on state to cross-couple connect the differential pair of amplification transistors at the oscillation core-mode.

19. The apparatus of claim 18 comprising a pair of gate switches controllable to switch a bias voltage of gates of the pair of neutralization transistors between a first Direct Current (DC) voltage and a second DC voltage, wherein the first DC voltage is to set the pair of neutralization transistors at the transistor-on state, wherein the second DC voltage is to set the pair of neutralization transistors at the transistor-off state.

20. The apparatus of claim 17 comprising voltage input circuitry controllable to connect a bias voltage to gates of the differential pair of amplification transistors at the amplification core-mode, and to disconnect the bias voltage from the gates of the differential pair of amplification transistors at the oscillation core-mode.

21. The apparatus of claim 17, wherein a drain of a first amplification transistor of the differential pair of amplification transistors is connected to a first differential output of the output terminal, wherein a drain of a second amplification transistor of the differential pair of amplification transistors is connected to a second differential output of the output terminal, wherein a first neutralization transistor of the pair of neutralization transistors is connected between a gate of the first amplification transistor and the drain of the second amplification transistor, wherein a second neutralization transistor of the pair of neutralization transistors is connected between a gate of the second amplification transistor and the drain of the first amplification transistor.

22. The apparatus of claim 1, wherein the AMP-OSC core comprises:
a differential pair of amplification transistors configured to amplify the input signal, and to provide the amplified signal to the output terminal at the amplification core-mode; and
a pair of oscillation transistors configured to generate the oscillating signal, and to provide the oscillating signal to the output terminal at the oscillation core-mode.

23. The apparatus of claim 1 comprising a Local Oscillator (LO) to generate an LO signal, wherein the input signal is based on the LO signal.

24. The apparatus of claim 1 comprising a controller configured to provide the control input to control setting of the AMP-OSC at the amplifying mode or at the oscillating mode.

25. The apparatus of claim 24, wherein the controller is configured to provide the second setting of the control input at a test mode to test a Radio Frequency (RF) chain comprising the AMP-OSC.

26. The apparatus of claim 1 comprising a radar device, the radar device comprising a plurality of Transmit (Tx) antennas connected to a plurality of Tx chains, a plurality of Rx antennas connected to a plurality of Rx chains, and a radar processor to generate radar information based on radar Rx signals processed by the Rx chains, wherein at least one of a radar Rx chain or a radar Tx chain comprises the AMP-OSC.
